(19) United States
(12) Patent Application Publication
(10) Pub. No.: US 2005/0016456 A1
(43) Pub. Date: Jan. 27, 2005

(54) Plasma processing device and plasma processing method

(76) Inventors: Noriyuki Taguchi, Otsu-shi (JP); Yasushi Sawada, Neyagawa-shi (JP); Kohichi Matsunaga, Kobe-shi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/490,293

(22) PCT Filed: Feb. 20, 2003
(86) PCT No.: PCT/JP03/01847

(30) Foreign Application Priority Data
Feb. 20, 2002 (JP) 2002-43868
Oct. 18, 2002 (JP) 2002-305002

(51) Int. Cl. C23C 16/00

(52) U.S. Cl. 118/723 E

(57) ABSTRACT

A plasma treatment apparatus and method are provided, which have the capability of maintaining a stable discharge, achieving a sufficient plasma treatment, and reducing plasma temperature. In this apparatus, electrodes are arranged to define a discharge space therebetween, and a dielectric material is disposed at a discharge-space side of at least one of the electrodes. A voltage is applied between the electrodes, while a plasma generation gas being supplied into the discharge space, to develop the discharge in the discharge space under a pressure substantially equal to atmospheric pressure, and provide the plasma generated by the discharge from the discharge space. A waveform of the voltage applied between the electrodes is an alternating voltage waveform without rest period. At least one of rising and falling times of the alternating voltage waveform is 100 μsec or less. A repetition frequency is in a range of 0.5 to 1000 kHz. An electric-field intensity applied between the electrodes is in a range of 0.5 to 200 kV/cm.

### TECHNICAL FIELD

The present invention relates to a plasma treatment apparatus and a plasma treatment method using the same apparatus, which can be utilized for cleaning a foreign substance such as organic materials on an object's surface to be treated, etching or peeling off resist materials, improving the adhesion of an organic film, reducing a metal oxide, film formation, pretreatment for plating or coating, and a surface treatment such as surface modification of various kinds of materials or parts, and particularly which are preferably applied to perform surface cleaning of electronic parts, for which precise connection is required.

### BACKGROUND ART

In the past, a plasma treatment such as surface modification has been performed to an object to be treated by defining a discharge space between a pair of opposed electrodes, applying a voltage between the electrodes while supplying a plasma generation gas into the discharge space to develop a discharge in the discharge space to obtain a plasma, and spraying the plasma or active species of the plasma from the discharge space to the object.

For example, in a spray-type plasma treatment method disclosed in Japanese Patent Early Publication No. 2001-126898, a high-frequency voltage of 13.56 MHz is applied between the electrodes to improve treatment performance such as plasma treatment speed, and an electric power is supplied to the electrodes through an impedance matching device connected to a high-frequency power source.

However, when the high-frequency voltage described above is applied between the electrodes to improve the plasma-treatment capability, there is a problem of increasing the temperature of the plasma ejected from the discharge space. In this case, since the object to be treated receives thermal damages by the heat of the plasma, this plasma treatment method is not available to a film having poor resistance to heat. In addition, the high-frequency power source and the impedance matching device are so expensive. Moreover, since it is needed to dispose the impedance matching device near the reaction vessel or the electrodes, a degree of freedom of design of the plasma treatment apparatus decreases.

Hence, it has been proposed to decrease a frequency of the voltage applied between the electrodes (i.e., a frequency for starting plasma). Thereby, it is possible to decrease the plasma temperature, and reduce the thermal damages of the object. In addition, since relatively inexpensive semiconductor devices become to be available to the power source, it is possible to reduce the cost of the power source device. Moreover, the impedance matching (device) is not needed. As a result, since it is allowed to extend a cable length between the power source and the electrodes, the degree of freedom of design of the plasma treatment apparatus increases.

However, a sufficient plasma treatment capability can not be obtained by simply decreasing the frequency of the voltage applied between the electrodes. In addition, to reduce the plasma temperature, it has been proposed to decrease the electric power applied to the electrodes. However, in this case, it becomes difficult to maintain the stable discharge, and there is a fear that the sufficient plasma treatment capability is not obtained.

In addition, in Mechanisms Controlling the Transition from Glow Silent Discharge to Streamer Discharge in Nitrogen (Nicolas Gherardi and Francoise Massines, IEEE TRANSACTIONS ON PLASMA SCIENCE, VOL.29, NO.3, PAGE 536-544, JUNE 2001), conditions for developing a uniform glow discharge in nitrogen atmosphere and a relationship between frequency (about 10 kHz or less) and applied voltage were reported.

According to the inventor's research of the present application, when using the conditions disclosed in the above-described report in the spray-type plasma treatment apparatus, the plasma treatment performance is very low, and therefore it is not appropriate for industrial use. To improve the plasma treatment performance, it is needed to increase the frequency of the voltage applied to generate the plasma.

However, there is a problem that as the frequency is increased to the high-frequency region, e.g., 13.56 MHz, the plasma temperature becomes higher. As a result, since the object to be treated receives thermal damage by the heat of the plasma, the above-described plasma treatment apparatus can not be used to perform the plasma treatment to the film having poor resistance to heat.

### SUMMARY OF THE INVENTION

Therefore, in consideration of the above-described problems, a concern of the present invention is to provide a plasma treatment apparatus, which has the capability of maintaining a stable discharge, providing a sufficient plasma treatment capability, and reducing the plasma temperature, and a plasma treatment method.

That is, the plasma treatment apparatus of the present invention is for developing a discharge in a-discharge space under a pressure substantially equal to atmospheric pressure by arranging a plurality of electrodes to define the discharge space therebetween, disposing a dielectric material at a discharge-space side of at least one of the electrodes, and applying a voltage between the electrodes, while supplying a plasma generation gas into the discharge space, and for providing a plasma generated by the discharge from the discharge space. The apparatus is characterized in that a waveform of the voltage applied between the electrodes is an alternating voltage waveform without rest period, at least one of rising and falling times of the alternating voltage waveform is 100 μsec or less, a repetition frequency is in a range of 0.5 to 1000 kHz, and an electric-field intensity applied between the electrodes is in a range of 0.5 to 200 kV/cm.

According to the present invention, it is possible to maintain the stable discharge and obtain a sufficient plasma treatment capability. In addition, the plasma temperature can be reduced. That is, since the plasma treatment is performed by use of a dielectric barrier discharge, it is not needed to use He. As a result, it is possible to reduce the cost of the plasma treatment. Moreover, since a larger electric power can be input to the discharge space to increase the plasma density, an improved plasma treatment capability is obtained. When the rising time is 100 μsec or less, uniform streamers can be easily generated in the discharge space to improve the uniformity of the plasma density in the discharge space. As a result, it is possible to uniformly perform the plasma treatment. In addition, when the repetition frequency of the alternating voltage waveform is in a range of 0.5 to 1000 kHz, it is possible to avoid an increase in plasma temperature and improve the plasma density of the dielectric barrier discharge. Therefore, it is possible to increase the plasma treatment capability, while preventing the occurrence of damages to the object to be treated and undesired discharge. Moreover, when the electric-field intensity applied between the electrodes is in the range of 0.5 to 200 kV/cm, it is possible to prevent the occurrence of arc discharge, increase the plasma density of the dielectric barrier discharge, and improve the plasma treatment capability, while preventing the occurrence of damages to the object.

In the above plasma treatment apparatus, it is preferred that a pulse-like high voltage is superimposed on the voltage having the alternating voltage waveform without rest period applied between the electrodes. In this case, by accelerating electrons in the discharge space, high-energy electrons can be generated. The high-energy electrons enhance ionization and excitation of the plasma generation to generate a high-density plasma. As a result, it is possible to increase the plasma treatment efficiency.

In the above plasma treatment apparatus, it is preferred that the pulse-like high voltage is superimposed after the elapse of a required time period from the occurrence of a change in voltage polarity of the alternating voltage waveform. In this case, an acceleration state of electrons in the discharge space can be changed. Therefore, by changing the timing of applying the pulse-like high voltage between the electrodes, it is possible to control the ionization and excitation of the plasma generation gas in the discharge space. As a result, the plasma suitable to the desired plasma treatment can be readily obtained.

In the above plasma treatment apparatus, it is preferred that the pulse-like high voltage is superimposed at plural times within one period of the alternating voltage waveform. In this case, the acceleration state of electrons in the discharge space can be easily changed. Therefore, by changing the timing of applying the pulse-like high voltage between the electrodes, it is possible to easily control the ionization or excitation of the plasma generation gas in the discharge space, and more readily obtain the plasma state suitable to the desired plasma treatment.

In the above plasma treatment apparatus, it is preferred that a rising time of the pulse-like high voltage is 0.1 μsec or less. In this case, it is possible to efficiently accelerate only the electrons in the discharge space, and enhance the ionization or excitation of the plasma generation gas in the discharge space to generate the high-density plasma. As a result, the plasma-treatment efficiency can be improved.

In the above plasma treatment apparatus, it is preferred that a pulse height value of the pulse-like high voltage is equal to or more than a maximum voltage value of the alternating voltage waveform. In this case, it is possible to efficiently perform the ionization or excitation of the plasma generation gas in the discharge space to generate the high-density plasma. As a result, the plasma-treatment efficiency can be improved.

In the above plasma treatment apparatus, it is preferred that the alternating voltage waveform without rest period applied between the electrodes is formed by superimposing alternating voltage waveforms having a plurality kinds of frequencies. In this case, electrons in the discharge space are accelerated by the voltage with a high-frequency component to generate high-energy electrons. Since the ionization or excitation of the plasma generation gas is efficiently realized in the discharge space by use of these high-energy electrons to generate the high-density plasma, it is possible to improve the plasma treatment efficiency.

A further concern of the present invention is to provide a plasma treatment apparatus comprising the following characteristics to achieve the above purpose. That is, the plasma treatment apparatus of the present invention is for developing a discharge in a discharge space under a pressure substantially equal to atmospheric pressure by arranging a plurality of electrodes to define the discharge space therebetween, disposing a dielectric material at a discharge-space side of at least one of the electrodes, and applying a voltage between the electrodes, while supplying a plasma generation gas into the discharge space, and for providing a plasma generated by the discharge from the discharge space. The present apparatus is characterized in that a waveform of the voltage applied between the electrodes is a pulse-like waveform.

According to the present invention, it is possible to maintain the stable discharge and obtain a sufficient plasma treatment capability. In addition, the plasma temperature can be reduced. That is, since the plasma treatment is performed by use of a dielectric barrier discharge, it is not needed to use He. As a result, it is possible to reduce the cost of the plasma treatment. Moreover, since a larger electric power can be input to the discharge space to increase the plasma density, an improved plasma treatment capability is obtained.

In the above plasma treatment apparatus, it is preferred that a rising time of the pulse-like waveform is 100 μsec or less. In this case, uniform streamers are easily generated in the discharge space, so that the uniformity of the plasma density is improved. As a result, it is possible to uniformly perform the plasma treatment.

In the above plasma treatment apparatus, it is preferred that a falling time of the pulse-like waveform is 100 μsec or less. In this case, uniform streamers are easily generated in the discharge space, so that the uniformity of the plasma density is improved. Therefore, it is possible to uniformly perform the plasma treatment.

In the above plasma treatment apparatus, it is preferred that a repetition frequency of the pulse-like waveform is in a range of 0.5 to 1000 kHz. In this case, it is possible to avoid an increase in plasma temperature, and improve the plasma density of the dielectric barrier discharge. Therefore, it is possible to increase the plasma treatment capability, while preventing the occurrence of damages to the object to be treated and undesired discharge.

In the above plasma treatment apparatus, it is preferred that an electric-field intensity applied between the electrodes is in a range of 0.5 to 200 kV/cm. In this case, it is possible to avoid the occurrence of arc discharge, and improve the plasma density of the dielectric barrier discharge. Therefore, it is possible to increase the plasma treatment capability, while preventing the occurrence of damages to the object to be treated.

In the above plasma treatment apparatus, it is preferred that the electrodes are disposed such that an electric field developed in the discharge space by applying the voltage between the electrodes is substantially parallel to a flow direction of the plasma generation gas in the discharge space. In this case; since the current density of streamers generated in the discharge space increases, it is possible to increase the plasma density and improve the plasma treatment performance.

In the above plasma treatment apparatus, it is preferred that the electrodes are disposed such that an electric field developed in the discharge space by applying the voltage between the electrodes is substantially orthogonal to a flow direction of the plasma generation gas in the discharge space. In this case, since the streamers are uniformly generated in the electrode plane, it is possible to improve the uniformity of the plasma treatment.

In the above plasma treatment apparatus, it is preferred that a flange portion, at which a part of the plasma generation gas supplied into the discharge space is allowed to stay, is formed between the electrodes. In this case, all of the space between opposed electrodes is used as the discharge space, and the occurrence of arc discharge outside the reaction vessel and between the electrodes can be prevented, so that the electric power applied between the electrodes is effectively used to develop the discharge. Therefore, it is possible to efficiently generate the stable plasma. In addition, since the discharge is developed between the opposed electrodes, a discharge start voltage becomes low at the flange portion. Therefore, it is possible to perform the ignition of the plasma with reliability. Moreover, since the plasma generated at the flange portion is added to the plasma generated at the discharge space, improved plasma treatment performance is obtained.

Another concern of the present invention is to provide a plasma treatment apparatus comprising the following characteristics to achieve the above purpose. That is, the plasma treatment apparatus of the present invention is provided with a reaction vessel having an opened end as an outlet and at least one pair of electrodes. By applying a voltage between the electrodes, while supplying a plasma generation gas into the reaction vessel, the apparatus generates a plasma in the reaction vessel under a pressure substantially equal to atmospheric pressure, and ejects the plasma from the outlet of the reaction vessel. In this plasma treatment apparatus, it is characterized in that the electrodes are disposed with a flange portion being formed between the electrodes and outside the reaction vessel, so that an electric field developed in a discharge space by applying the voltage between the electrodes is substantially parallel to a flow direction of the plasma generation gas in the discharge space.

According to the present invention, it is possible to stably maintain the discharge and obtain a sufficient plasma treatment capability. In addition, the plasma temperature can be reduced. That is, since the plasma treatment is performed by use of a dielectric barrier discharge, it is not needed to use He. As a result, it is possible to reduce the cost of the plasma treatment. In addition, it is possible to increase the input electric power to the discharge space to obtain a higher plasma density. As a result, the plasma treatment capability is improved. Moreover, since the occurrence of dielectric breakdown between the electrodes and outside the reaction vessel can be prevented, it is possible to stably start and keep the plasma at the discharge space in the reaction vessel, while preventing the problem of increasing the plasma temperature. Consequently, the plasma treatment is achieved with reliability.

In the above plasma treatment apparatus, it is preferred that a waveform of the voltage applied between the electrodes is a pulse-like waveform or an alternating voltage waveform without rest period. In this case, it is possible to stably maintain the discharge and obtain a sufficient plasma treatment capability. In addition, the plasma temperature can be reduced. That is, since the plasma treatment is performed by use of a dielectric barrier discharge, it is not needed to use He. As a result, it is possible to reduce the cost of the plasma treatment. In addition, it is possible to increase the input electric power to the discharge space and obtain a higher plasma density. As a result, the plasma treatment capability is improved.

In the above plasma treatment apparatus, it is preferred that a rising time of the pulse-like waveform or the alternating voltage waveform without rest period is 100 μsec or less. In this case, since uniform streamers are easily generated in the discharge space, the uniformity of the plasma density in the discharge space can be improved. Therefore, it is possible to uniformly perform the plasma treatment.

In the above plasma treatment apparatus, it is preferred that a falling time of the pulse-like waveform or the alternating voltage waveform without rest period is 100 μsec or less. In this case, since uniform streamers are easily generated in the discharge space, the uniformity of the plasma density in the discharge space can be improved. Therefore, it is possible to uniformly perform the plasma treatment.

In the above plasma treatment apparatus, it is preferred that a repetition frequency of the pulse-like waveform or the alternating voltage waveform without rest period is in a range of 0.5 to 1000 kHz. In this case, it is possible to avoid the problem of increasing the plasma temperature, and increase the plasma density of the dielectric barrier discharge. Therefore, it is possible to prevent damages to the object and undesired discharge, and improve the plasma treatment capability.

In the above plasma treatment apparatus, it is preferred that an electric-field intensity applied between the electrodes is in a range of 0.5 to 200 kV/cm. In this case, it is possible to prevent the occurrence of arc discharge, and increase the plasma density of the dielectric barrier discharge. As a result, it is possible to prevent damages to the object, and improve the plasma treatment capability.

In the above plasma treatment apparatus, it is preferred that discharge space is partially narrowed. In this case, it is possible to prevent a situation that the streamers are generated so as to move around the inner surface of the reaction vessel, and a jet-like plasma is ejected from the outlet while shaking. As a result, the instability of the plasma treatment can be reduced.

In the above plasma treatment apparatus, it is preferred that a filling material is provided between the electrode and the flange portion, so that the electrode is connected to the flange portion through the filling material. In this case, it is possible to prevent the occurrence of corona discharge by completely occluding a clearance between the electrodes and the flange portion. In addition, since the corrosion of the electrodes is prevented, a longer operating life of the electrodes can be achieved.

In the above plasma treatment apparatus, it is preferred that the voltage is applied such that both of the electrodes are in a floating state with respect to the ground potential. In this case, since the voltage of the plasma can be reduced with respect to the ground, it is possible to prevent the occurrence of dielectric breakdown between the plasma and the object to be treated. That is, by preventing the occurrence of arc discharge from the plasma toward the object, it is possible to prevent a situation that damages of the object are caused by the arc discharge.

In the above plasma treatment apparatus, it is preferred that the plasma generation gas includes a rare gas, nitrogen, oxygen, air, hydrogen or a mixture gas thereof. In this case, it is possible to perform modifying a surface of the object by use of the plasma generation gas of the rare gas or nitrogen, removing an organic material by use of the plasma generation gas of oxygen, both of the surface modification and the removal of the organic material by use of the plasma generation gas of the air, reducing a metal oxide by use of the plasma generation gas of hydrogen, both of the surface modification and the removal of the organic material by use of the plasma generation gas of the mixture gas of the rare gas and oxygen, and reducing the metal oxide by use of the plasma generation gas of the mixture gas of the rare gas and hydrogen.

In the above plasma treatment apparatus, it is preferred that the plasma generation gas is a mixture gas obtained by mixing CF₄, SF₆, NF₃ or a mixture thereof with a rare gas, nitrogen, oxygen, air, hydrogen or a mixture thereof at a volume ratio of 2 to 40%. In this case, it is possible to efficiently perform cleaning an organic material on the object's surface, peeling off a resist film, etching an organic film, surface cleaning an LCD or a glass plate, silicon or resist etching, and ashing.

In the above plasma treatment apparatus, it is preferred that the plasma generation gas is a mixture gas obtained by mixing oxygen such that a volume ratio of oxygen with respect to nitrogen is 1% or less. In this case, it is possible to efficiently perform cleaning an organic material on the object's surface, peeling off a resist film, etching an organic film, and surface cleaning an LCD or a glass plate.

In the above plasma treatment apparatus, it is preferred that the plasma generation gas is a mixture gas obtained by mixing the air such that a volume ratio of the air with respect to nitrogen is 4% or less. In this case, it is possible to efficiently perform cleaning an organic material on the object's surface, peeling off a resist film, etching an organic film, and surface cleaning an LCD or a glass plate.

In the above plasma treatment apparatus, it is preferred that the plasma generation gas is supplied into the discharge space such that a flow velocity of the plasma generation gas provided from the outlet in a non-discharge state is in a range of 2 m/sec to 100 m/sec. In this case, it is possible to obtain a high plasma-treatment effect without the occurrence of unusual discharge or a decrease in modification effect.

In addition, another concern of the present invention is to provide a plasma treatment method using the plasma treatment apparatus described above. According to the plasma treatment method of the present invention, it is possible to obtain a sufficient plasma treatment capability while maintaining the stable discharge, and also reduce the plasma temperature.

Further characteristics of the present invention and effects brought thereby will be understood from detail explanation of the invention and examples described below.

### BRIEF EXPLANATION OF DRAWINGS

FIG. 1 is a perspective view illustrating an embodiment of the present invention;

FIGS. 2A and 2B are cross-sectional views showing arrangements of electrodes and dielectric materials for developing a dielectric barrier discharge;

FIG. 3 is a cross-sectional view illustrating a developing state of the dielectric barrier discharge;

FIG. 4 is a graph showing changes in applied voltage and gap current over time in the developing state of the dielectric barrier discharge;

FIG. 5 is a circuit diagram showing an equivalent circuit for the dielectric barrier discharge;

FIG. 6 is a graph showing changes in power supply voltage, equivalent capacitance Cg of a discharge space (discharge gap portion), and plasma impedance Rp over time in the developing state of the dielectric barrier discharge;

FIGS. 7A and 7B are cross-sectional views illustrating a state of inverting polarity of power source;

FIGS. 8A, 8B, 8C and 8D are explanatory diagrams of alternating voltage waveforms used in the present invention;

FIGS. 9A, 9B, 9C, 9D and 9E are explanatory diagrams of alternating voltage waveforms used in the present invention;

FIGS. 10A and 10B are explanatory diagrams of waveforms each obtained by superimposing a pulse-like high voltage on a voltage having the alternating voltage waveform used in the present invention;

FIGS. 11A, 11B, 11C, 11D and 11E are explanatory diagrams of pulse-like waveforms used in the present invention;

FIG. 12 is an explanatory diagrams for defining rising and falling times of the present invention;

FIGS. 13A, 13B and 13C are explanatory diagrams for defining a repetition frequency of the present invention;

FIGS. 14A and 14B are explanatory diagrams for defining an electric-field-intensity of the present invention;

FIG. 15 is a perspective view of another embodiment of present invention;

FIG. 16 is a perspective view of another embodiment of present invention;

FIG. 17 is a cross-sectional view of another embodiment of present invention;

FIG. 18 is a perspective view of another embodiment of present invention;

FIGS. 19A and 19B are front and plan views of another embodiment of present invention;

FIG. 20 is a front view of another embodiment of present invention;

FIG. 21 is a perspective view of another embodiment of present invention;

FIG. 22 is a perspective view of another embodiment of present invention;

FIG. 23 is a perspective view of another embodiment of present invention;

FIG. 24 is a cross-sectional view of another embodiment of present invention;

FIG. 25 is a perspective view of another embodiment of present invention;

FIG. 26 is a partially cross-sectional view of another embodiment of present invention;

FIG. 27 is a partially cross-sectional view of another embodiment of present invention;

FIG. 28 is a cross-sectional view of another embodiment of present invention;

FIG. 29 is a circuit diagram illustrating a power source used in the embodiment 1 of the present invention;

FIG. 30 is a circuit diagram showing an H-bridge switching circuit in FIG. 29;

FIG. 31 is a timing chart explaining an operation of the H-bridge switching circuit shown in FIG. 30;

FIG. 32 is a timing chart explaining an operation of the power source shown in FIG. 29;

FIG. 33 is a partially cross-sectional view of another embodiment of present invention;

FIG. 34 is a partially cross-sectional view of another embodiment of present invention;

FIG. 35 is a partially cross-sectional view of another embodiment of present invention;

FIGS. 36A and 36B are explanatory diagrams illustrating the generation of streamers in FIG. 1;

FIG. 37 is a partially cross-sectional view of another embodiment of present invention;

FIG. 38 is a partially cross-sectional view of another embodiment of present invention;

FIG. 39 is a partially cross-sectional view of another embodiment of present invention;

### BEST MODE FOR CARRYING OUT THE INVENTION

The present invention is explained in detail according to preferred embodiments.

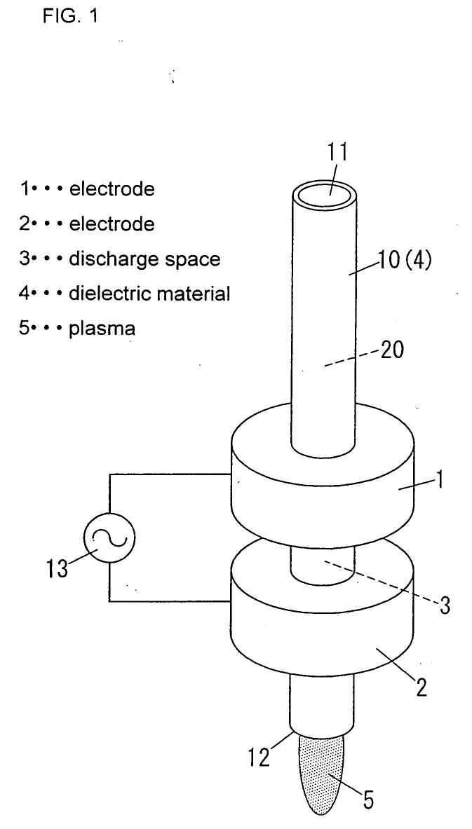

A plasma treatment apparatus of the present invention is shown in FIG. 1. This apparatus is provided with a reaction vessel 10 and a plurality (pair) of electrodes 1, 2.

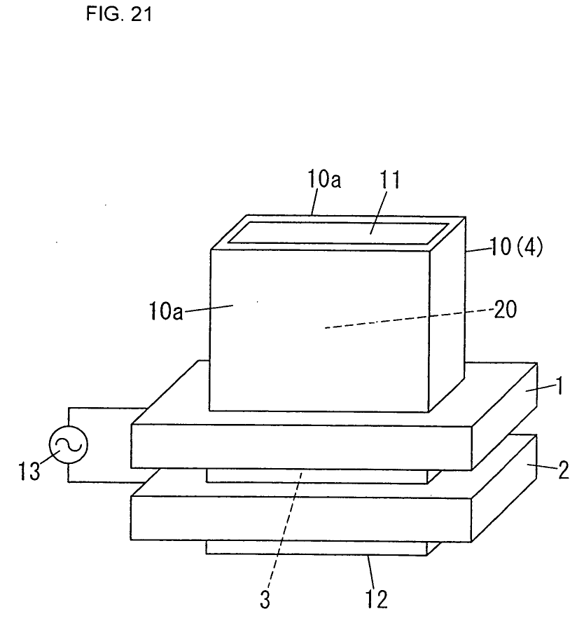

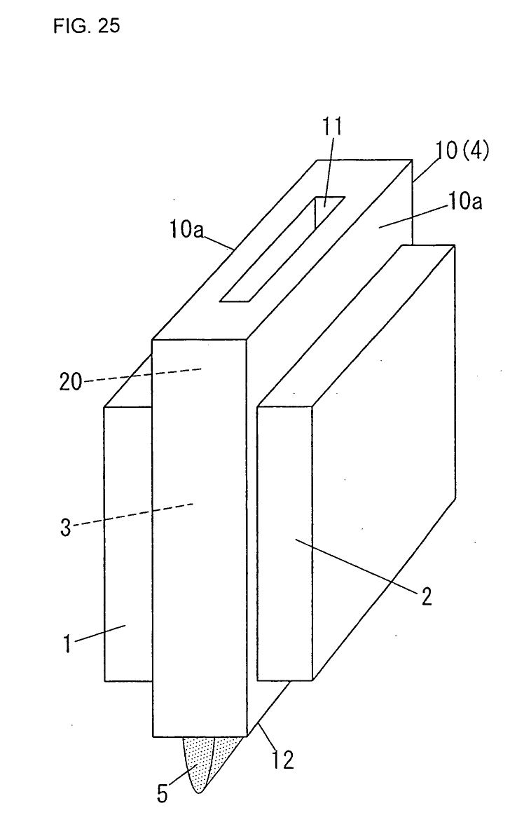

The reaction vessel 10 is made of a dielectric material (insulating material) having a high melting point, for example, a glass material such as quarts glass or a ceramic material such as alumina, yttria or zirconia. However, it is not limited to those materials. In addition, the reaction vessel 10 is of a cylindrical shape that linearly extends up and down by a sufficient length. An inner space of the reaction vessel 10 is used as a gas flow channel 20. An upper end of the gas flow channel 20 is used as a gas inlet 11 opened over the entire top surface of the reaction vessel 10. A lower end of the gas flow channel 20 is used as a gas outlet 12 opened over the entire bottom surface of the reaction vessel 10. For example, an inner diameter of the reaction vessel 10 can be 0.1 to 10 mm. When the inner diameter is smaller than 0.1 mm, a plasma generation region becomes too narrow, so that the plasma can not be efficiently generated. On the other hand, when the inner diameter is larger than 10 mm, a large amount of gas is needed to efficiently generate the plasma because the gas flow velocity becomes slow at the plasma generation region. As a result, the entire efficiency lowers in industrial scale. According to the inventor's research, it is preferred that the inner diameter is in the range of 0.2 to 2 mm to efficiently generate the plasma by use of a minimized amount of the plasma generation gas. In addition, when using the reaction vessel 10 having a large width, as shown in FIGS. 21 and 25, the narrow side (the thickness direction) corresponds to the inner diameter, which can be in a range of 0.1 to 10 mm, and preferably 0.2 to 2 mm.

The electrodes 1, 2 are formed in a doughnut shape and made of a conductive metal material such as copper, aluminum, brass, a stainless steel having corrosion resistance (e.g., SUS304), titanium, 13% chromium steel or SUS410. In addition, a cooling-water circulation channel may be formed in the interior of the electrodes 1, 2. By circulating the cooling water in the circulation channel, the electrodes 1, 2 can be cooled. Moreover, a plating film such as gold plating may be formed on the electrode (outer) surfaces 1, 2 for the purpose of preventing corrosion.

The electrodes 1, 2 are placed outside the reaction vessel 10 such that an inner circumferential surface of the electrode contacts the outer circumferential surface of the reaction vessel over the entire circumference thereof. In addition, the electrodes 1, 2 are disposed to face each other in the longitudinal direction, i.e., the up-and-down direction of the reaction vessel 10. In the reaction vessel 10, a region between the top end of the upper electrode 1 and the bottom end of the lower electrode 2 is defined as a discharge space 3. That is, a part of the gas flow channel 20 positioned between the top end of the upper electrode 1 and the bottom end of the lower electrode 2 is defined as the discharge space 3. Therefore, the side wall of the reaction vessel 10 made of the dielectric material 4 is provided at the discharge-space side of the electrodes 1, 2. The discharge space 3 communicates with the gas inlet 11 and the outlet 12. The plasma generation gas flows in the gas flow channel 20 from the gas inlet 11 toward the outlet 12. Therefore, the electrodes 1, 2 are arranged side by side in a direction substantially parallel to the flow direction of the plasma generation gas in the gas flow channel 20.

A power source 13 for generating a voltage is connected to the electrode 1, 2. The upper electrode 1 is formed as a high-voltage electrode, and the lower electrode 2 is formed as a low-voltage electrode. When the lower electrode 2 is connected to the ground, the lower electrode 2 is formed as the ground electrode. It is preferred that a distance between the electrodes 1, 2 is in a range of 3 to 20 mm to stably generate the plasma. By applying the voltage between the electrodes 1, 2 from this power source 13, an alternating or pulse-like electric field can be applied to the discharge space 3 through the electrodes 1, 2. The alternating (alternate current) electric field has an electric-field waveform (e.g., sinusoidal wave) with nothing or little of rest period (a time period of the stationary state that the voltage is zero). The pulse-like electric field has an electric-field waveform with a rest period.

By using the above plasma treatment apparatus, a plasma treatment can be performed as follows. The plasma generation gas is supplied into the reaction vessel 10 from the gas inlet 11 to flow in the gas flow channel 20 from top to down, so that the plasma generation gas is provided to the discharge space 3. On the other hand, a voltage is applied between the electrodes 1, 2 so that a discharge is developed in the discharge space 3 under a pressure substantially equal to atmospheric pressure (93.3 to 106.7 kPa (700 to 800 Torr)). By this discharge, the plasma generation gas supplied into the discharge space 3 becomes a plasma 5 including active species. The plasma 5 is successively provided downward from the discharge space 3 through the outlet 12, and sprayed in a jet-like manner on an object to be treated placed under the outlet 12. Thus, the plasma treatment can be performed to the object.

A distance between the object and the outlet 12 opened over the entire bottom surface of the reaction vessel 10 is adjustable according to the gas flow amount and the plasma generation density. For example, the distance can be set in a range of 1 to 20 mm. When the distance is smaller than 1 mm, there is a fear that the object contacts the reaction vessel 10 because of up-and-down vibrations of the object during conveying or a distortion or warping of the object. When the distance is larger than 20 mm, the plasma treatment effect lowers. According to the inventor's research of the present application, it is preferred that the distance is in a range of 2 to 10 mm to efficiently generate the plasma with a minimized gas flow amount.

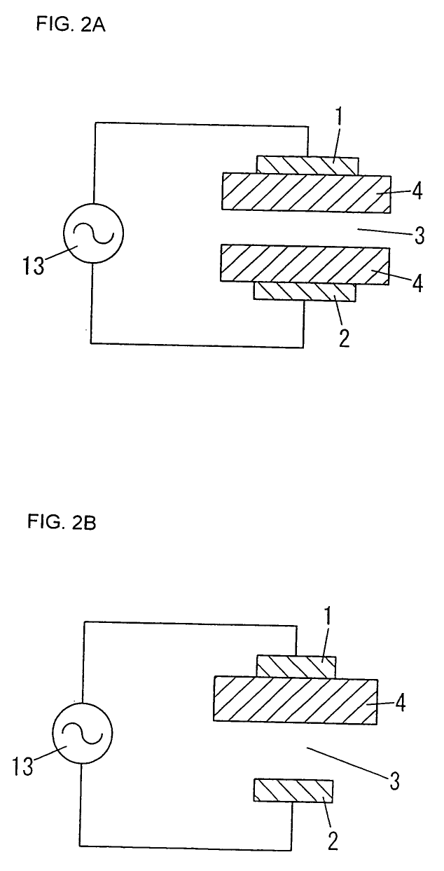

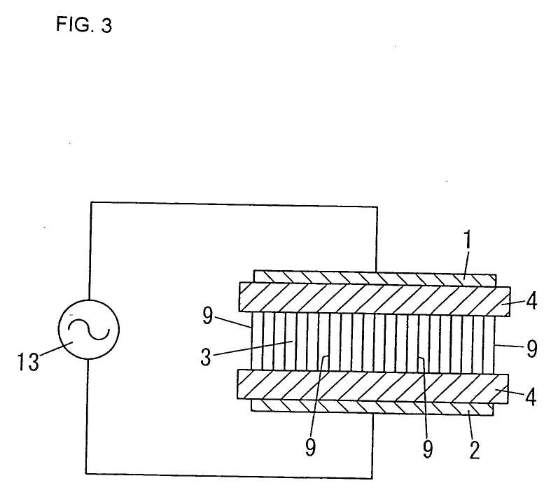

In the present invention, the discharge developed in the discharge space 3 is a dielectric barrier discharge. The fundamental features of the dielectric barrier discharge are explained below (Reference: Author Izumi Hayashi “High Voltage Plasma Technology” P35, MARUZEN Co., LTD.). The dielectric barrier discharge is a discharge phenomenon, which is obtained in the discharge space 3 by placing a pair of electrodes 1, 2 at opposed positions to define the discharge space 3 between the electrodes 1, 2, forming a (solid) dielectric material 4 on a surface of the respective electrode 1, 2 at the discharge-space 3 side, as shown in FIG. 2A, or forming the dielectric material 4 on the surface of one of the electrodes 1 (or the other electrode 2) at the discharge-space 3 side, as shown in FIG. 2B, to prevent the occurrence of direct discharge between the electrodes 1, 2, and applying an alternating voltage between the electrodes by the power source 13 under this condition. Thus, when the alternating high voltage is applied between the electrodes under the condition that the discharge space 3 is filled with the gas of approximately 1 atm, infinite number of extremely fine light lines uniformly occur in a direction parallel to the electric field in the discharge space 3, as shown in FIG. 3. The light lines are caused by streamers 9. Electric charges of the streamers 9 can not flow into the electrodes 1, 2 because the electrodes are covered with the dielectric material 4. Therefore, the electric charges in the discharge space 3 are stored in the dielectric material 4 on the electrode surface (This is called as wall charges.).

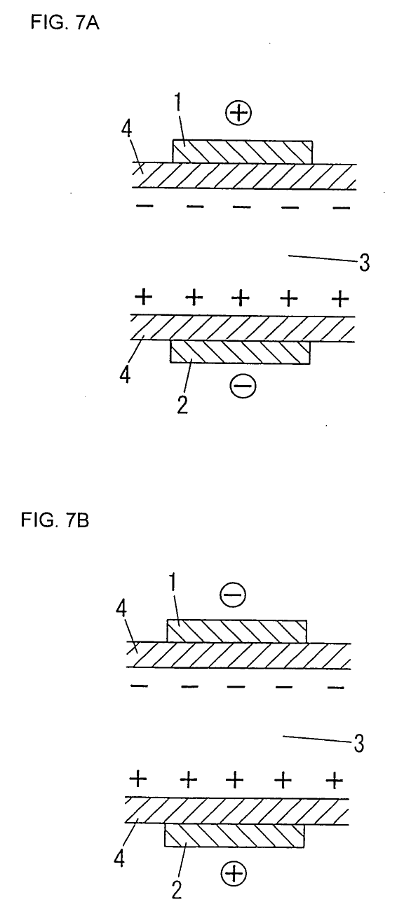

In the state of FIG. 7A, the electric field brought by the wall charges is in an opposite direction to the alternating electric field supplied from the power source 13. Therefore, when the wall charges increase, the electric field of the discharge space 3 decreases, so that the dielectric barrier discharge stops. However, in (the state of FIG. 7B) the half cycle of the next alternating voltage from the power source 13, since the electric field brought by the wall charges is in agreement with the direction of the alternating electric field supplied from the power source 13, the dielectric barrier discharge is easily developed. That is, once the dielectric barrier discharge starts, it can be subsequently maintained at a relatively low voltage.

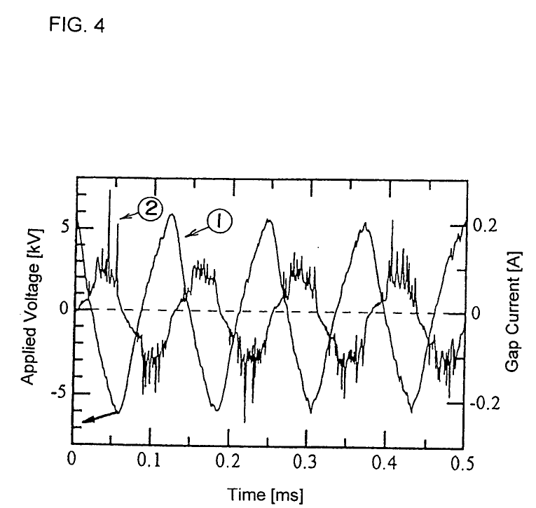

Infinite number of streamers generated in the dielectric barrier discharge is just the dielectric barrier discharge developed in the discharge space 3. Therefore, the number of streamers generated and a current value flowing in each of the streamers influence the plasma density. An example of the current-voltage characteristic of the dielectric barrier discharge is shown in FIG. 4. As apparent from this current-voltage characteristic, the current waveform (the waveform of gap current) in the dielectric barrier discharge is equal to that obtained by superimposing a spike-like current on a sinusoidal current waveform. The spike-like current is the current flowing in the discharge space 3 when the streamers 9 are generated. In FIG. 4, the numerals \mathring{1} and \mathring{2} designate the waveform of the applied voltage and the waveform of the gap current, respectively.

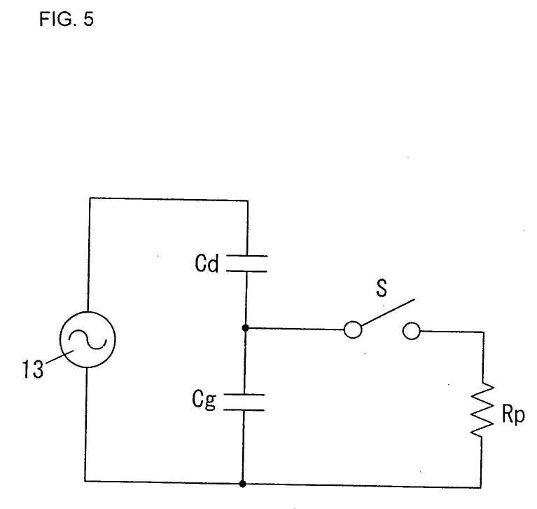

An equivalent circuit of the dielectric barrier discharge is shown in FIG. 5. Each of the symbols in the figure has the following meaning.
Cd: Capacitance of the dielectric material 4 on the electrode 1, 2
Cg: Equivalent capacitance of the discharge space 3 (discharge gap portion)
Rp: Plasma impedance

The infinite number of streamers 9 generated in the discharge space 3 mean that electric current flows in Rp when the ON-OFF operation of the switch S shown in the figure is performed. As described before, the plasma density is influenced by the number of streamers 9 generated and the current value flowing in the respective streamer 9. From the aspect of the equivalent circuit, it is defined by the frequency of the ON-OFF operation, ON period, and the current value during the ON period of the switch S.

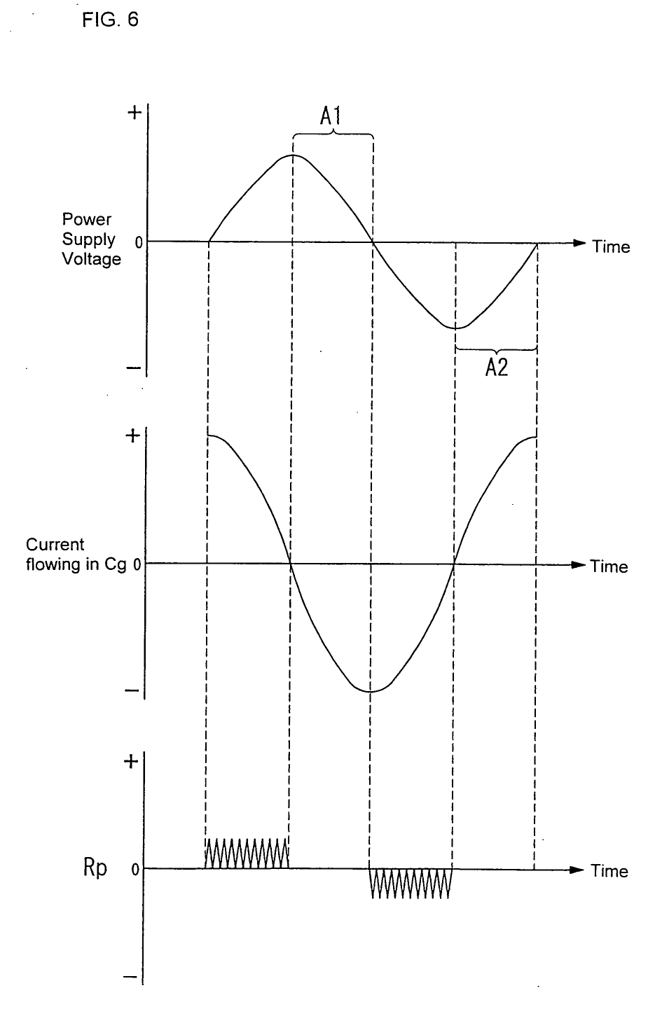

According to this equivalent circuit, a behavior of the dielectric barrier discharge is briefly explained. FIG. 6 shows pattern diagrams of the voltage waveform applied by the power source 13 and the current waveforms of Cg and Rp. Since the electric current flowing in Cg is the charge and discharge current of an equivalent capacitor of the discharge space 3, it is not the current determining the plasma density. On the contrary, the electric current that flows in Rp instantly when the switch S is turned on is just the electric current of the streamer 9. As the duration of this electric current and the current value increase, the plasma density becomes higher.

As described above, when the wall charges increase, so that the electric field of the discharge space 3 lowers, the dielectric barrier discharge stops. Therefore, the dielectric barrier discharge does not develop at a region (the region A1 of FIG. 6), at which the applied voltage to the electrodes 1, 2 goes beyond the maximum value and then decreases, or a region (the region A2 of FIG. 6), at which the applied voltage to the electrodes 1, 2 goes beyond the minimum value and then increases, and only the charge and discharge current of the capacitor flows until the polarity of the alternating voltage applied by the power source 13 inverts. Therefore, by reducing the period of the regions A1 or the period of the region A2, the stop period of the dielectric barrier discharge is shortened to increase the plasma density. As a result, it is possible to improve the plasma treatment capability (efficiency).

As the plasma generation gas, it is possible to use a rare gas, nitrogen, oxygen, air or hydrogen by itself or a mixture thereof. As the air, a dried air having nothing or little of moisture is preferably used. In the present invention, when using the dielectric barrier discharge that is not glow discharge, it is not needed to use a specific gas such as the rare gas. Therefore, the plasma-treatment cost can be reduced. In addition, to stably generate the dielectric barrier discharge, it is preferred to use a rare gas other than helium, or a mixture of the rare gas other than helium and a reactive gas as the plasma generation gas. As the rare gas, argon, neon or krypton can be used. In consideration of the stability of discharge and the economical efficiency, it is preferred to use argon. Thus, when the dielectric barrier discharge that is not glow discharge is used in the present invention, it is not needed to use helium. Therefore, the plasma-treatment cost can be reduced. The kinds of the reactive gas can be optionally selected according to the treatment purpose. For example, in the case of cleaning an organic material on the object's surface, peeling off a resist film, etching an organic film or surface cleaning an LCD or a glass plate, it is preferred to use an oxidative gas such as oxygen, air, CO₂, or N₂O. In addition, a fluorine containing gas such as CF₄, SF₆ or NF₃ may be used as the reactive gas. When performing ashing or etching silicon or a resist, it is effective to use the fluorine containing gas. Moreover, in the case of reducing a metal oxide, it is possible to use a reduction gas such as hydrogen or ammonia.

It is preferred that an additive amount of the reaction gas is 10 vol % or less, and-preferably in a range of 0.1 to 5 vol % with respect to the total amount of rare gas. When the additive amount of the reactive gas is less than 0.1 vol %, the treatment effect may lower. When the additive amount is more than 10 vol %, the barrier discharge may become unstable.

As the plasma generation gas, when using a mixture gas obtained by mixing a fluorine containing gas such as CF₄, SF₆, NF₃ by itself or a mixture thereof with a rare gas, nitrogen, oxygen, air, hydrogen by itself or a mixture thereof, it is preferred that a volume ratio of the fluorine containing gas with respect to the total amount of the plasma generation gas is in a range of 2 to 40%. When the volume ratio is less than 2%, the treatment effect is sufficiently obtained. When it is more than 40%, the discharge becomes unstable.

In the case of using a mixture of nitrogen and oxygen as the plasma generation gas, it is preferred to mix oxygen at a volume ratio of 0.005% to 1% with respect to nitrogen. In the case of using a mixture gas of the air and nitrogen as the plasma generation gas, it is preferred to mix the air at a volume ratio of 0.02% to 4% with respect to nitrogen. In these cases, it is possible to efficiently perform cleaning the organic material on the object's surface, peeling off the resist film, etching the organic film, surface cleaning the LCD and the glass plate.

When two kinds or more of the gases are mixed to generate the plasma 5, those gases may be previously mixed before being supplied into the discharge space 3. Alternatively, after the plasma is generated by one kind or more of the gases, another gas may be mixed to the plasma 5 ejected from the outlet 12.

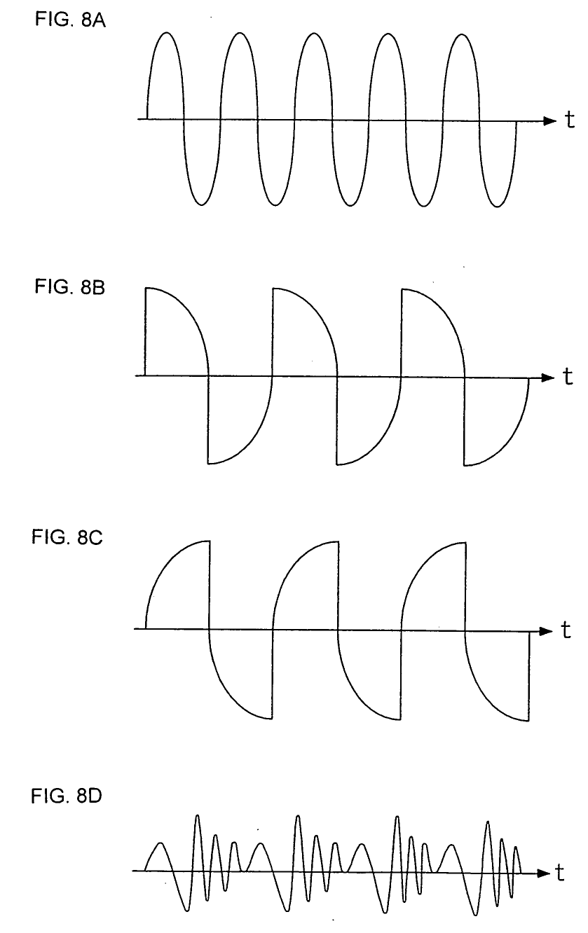

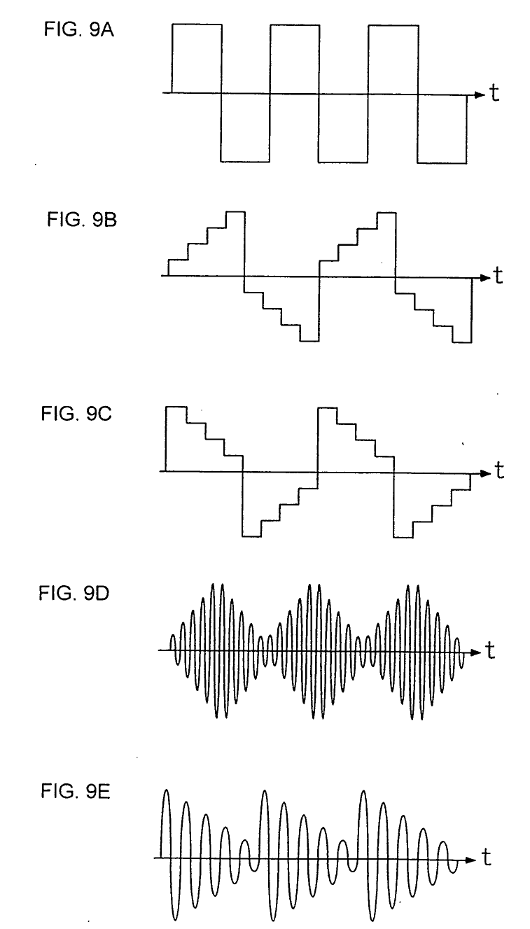

In the present invention, an alternating voltage waveform with no rest period can be used as the waveform of the voltage applied between the electrodes 1, 2. For example, the alternating voltage waveform with no rest period used in the present invention varies with time, as shown in FIGS. 8A to 8D, and FIGS. 9A and 9E (the horizontal axis is time (t)). FIG. 8A shows a sinusoidal waveform. In FIG. 8B, a rapid voltage change shown by the amplitude happens in a short rising time (a period required to allow the voltage to reach the maximum value from zero cross), and then a slow voltage change happens in a long falling time (a period required to allow the voltage to reach the zero cross from the maximum value), which is longer than the rising time. In FIG. 8C, a rapid voltage change happens in a short falling time, and a slow voltage change happens in a long rising time, which is longer than the falling time. FIG. 8D shows an oscillating waveform obtained by successively repeating a repetition unit cycle, in which an oscillating wave is damped or amplified within a constant period. FIG. 9A shows a rectangular waveform. In FIG. 9B, a rapid voltage change happens in a short falling time, and a slow voltage change happens in a stepwise manner within a long rising time, which is longer than the falling time. In FIG. 9C, a rapid voltage change happens in a short rising time, and a slow voltage change then happens in a stepwise manner within a long falling time, which is longer than the rising time. FIG. 9D shows an amplitude-modulated waveform. FIG. 9E shows a damped oscillation waveform.

At least one of the rising and falling times of the alternating voltage waveform, and preferably both of them can be 100 μsec or less. When both of the rising and falling times are more than 100 μsec, the plasma density in the discharge space 3 can not be increased, so that the plasma treatment capability lowers. In addition, it becomes difficult to uniformly generate the streamers. As a result, the plasma treatment may not be performed uniformly. It is preferred to minimize the rising and falling times. Therefore, the lower limit is not specifically limited. However, in consideration of a conventional power source with the shortest rising and falling times, the lower limit may be approximately 40 nsec. By technical developments in the future, if the rising and falling times can be further shortened, it is preferred to use the rising and falling times shorter than 40 nsec. It is preferred that the rising and falling times are 20 μsec or less, and particularly 5 μsec or less.

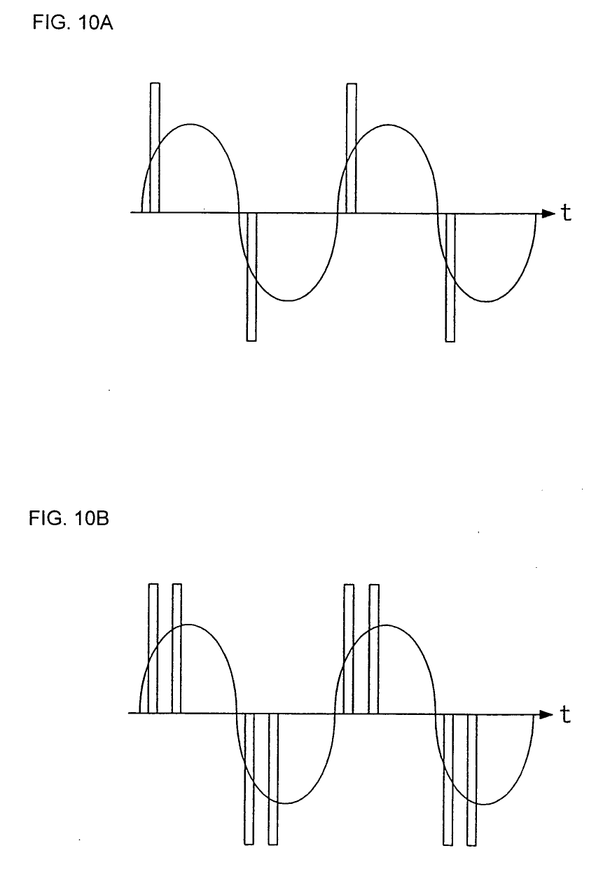

In addition, as shown in FIG. 10A, a voltage having the alternating voltage waveform with no rest period, on which a pulse-like high voltage is superimposed, may be applied between the electrodes 1, 2. By superimposing the pulse-like high voltage on the voltage of the alternating voltage waveform, electrons are accelerated in the discharge space 3 to generate high-energy electrons. The plasma generation gas is efficiently ionized or excited in the discharge space 3 by the high-energy electrons to obtain a high-density plasma. As a result, the plasma-treatment efficiency can be improved.

Thus, in the case of superimposing the pulse-like high voltage on the voltage of the alternating voltage waveform, it is preferred to superimpose the pulse-like high voltage after the elapse of a required time period from the occurrence of a change in voltage polarity of the alternating voltage waveform, and change an applying time of the pulse-like high voltage to be superimposed. Thereby, it is possible to change the accelerating state of electrons in the discharge space 3. Therefore, by changing the timing of applying the pulse-like high voltage between the electrodes 1, 2, it is possible to control the ionization or excitation state of the plasma generation gas in the discharge space 3, and readily create a plasma state suitable for a desired plasma treatment.

In addition, as shown in FIG. 10B, the pulse-like high voltage may be superimposed at plural times within one period of the alternating voltage waveform. In this case, it is possible to more easily change the accelerating state of electrons in the discharge space 3, as compared with the case of FIG. 10A. Therefore, by changing the timing of applying the pulse-like high voltage between the electrodes 1, 2, it is possible to control the ionization or excitation state of the plasma generation gas in the discharge space 3, and readily create a plasma state suitable for a desired plasma treatment.

In addition, it is preferred that the rising time of the pulse-like high voltage to be superimposed is 0.1 μsec or less. When the rising time of the pulse-like high voltage is more than 0.1 μsec, ions in the discharge space 3 can move following the pulse-like voltage, so that it may be difficult to efficiently accelerate only the electrons. Therefore, by using the rising time of 0.1 μsec or less of the pulse-like high voltage, it is possible to efficiently ionize or excite the plasma generation gas in the discharge space 3, and generate a high-density plasma. As a result, the plasma-treatment efficiency can be improved. It is also preferred that the falling time of the pulse-like high voltage to be superimposed is 0.1 μsec or less.

In addition, it is preferred that a pulse height value of the pulse-like high voltage is equal to or more than the maximum voltage value of the alternating voltage waveform. When the pulse height value is less than the maximum voltage value of the alternating voltage waveform, the effect brought by superimposing the pulse-like high voltage lowers, so that the plasma state may become the same as the case of not superimposing the pulse-like high voltage. Therefore, when the pulse height value of the pulse-like high voltage is equal to or more than the maximum voltage value of the alternating voltage waveform, the plasma generation gas is efficiently ionized or excited in the discharge space 3 to generate a high-density plasma. As a result, the plasma-treatment efficiency can be improved.

In addition, it is preferred that the alternating voltage waveform with no rest period applied between the electrodes 1, 2 is formed by superimposing alternating voltage waveforms having a plurality kinds of frequencies, as shown in FIGS. 8A to 8D and FIGS. 9A to 9E. In this case, electrons in the discharge space 3 are accelerated by the voltage(s) with high-frequency component(s) to generate high-energy electrons. Therefore, the plasma generation gas can be efficiently ionized or excited in the discharge space 3 by the high-energy electrons to obtain a high-density plasma. As a result, the plasma-treatment efficiency can be improved.

It is preferred that a repetition frequency of the voltage having the alternating voltage waveform with no rest period applied between the electrodes 1, 2 is in a range of 0.5 to 1000 kHz. When this repetition frequency is less than 0.5 kHz, the number of streamers 9 generated in unit time decreases to decrease the plasma density of the dielectric barrier discharge. As a result, the plasma treatment capability (efficiency) may lower. On the other hand, when the repetition frequency is more than 1000 kHz, the number of streamers 9 generated in unit time increases to improve the plasma density. However, there is a fear that arc discharge easily occurs, and the plasma temperature increases.

In addition, it is preferred that an electric-field intensity of the alternating voltage waveform with no rest period applied between the electrodes 1, 2 is in a range of 0.5 to 200 kV/cm although it can be changed in accordance with a distance (gap length) between the electrodes 1, 2, kinds of the plasma generation gas, and the kinds of the object to be treated by the plasma. When the electric-filed intensity is less than 0.5 kV/cm, the plasma density of the dielectric barrier discharge decreases, so that the plasma treatment capability (efficiency) may lower. On the other hand, when the electric-filed intensity is more than 200 kV/cm, there is a fear that arc discharge easily occurs to give damages to the object.

In the plasma treatment apparatus of the present invention, since the plasma treatment is performed by generating the plasma 5 of a large number of streamers 9 from the dielectric barrier discharge, and spraying the plasma 5 to the object surface, it is not needed to use He, which has been used to generate glow discharge in the past, and the plasma-treatment cost can be reduced. In addition, since the dielectric barrier discharge is used in place of the glow discharge, a larger electric power can be input to the discharge space 3 to increase the plasma density. As a result, the plasma treatment capability is improved. That is, in the glow discharge, electric current flows at a rate of only one electric current pulse every half cycle of the voltage. On the other hand, in the dielectric barrier discharge, a large number of electric-current pulses occur in the form corresponding to the streamers 9. Therefore, it is possible to increase the input power in the dielectric barrier discharge. In the plasma treatment apparatus using the glow discharge of the past, a magnitude of the electric power input in the discharge space 3 is approximately 2 W/cm² at the maximum. However, in the present invention, up to about 5 W/cm² of the electric power can be supplied into the discharge space 3. In addition, since at least one of the rising and falling times of the alternating voltage waveform is 100 μsec or less, it is possible to increase the plasma density in the discharge space 3, and improve the plasma treatment capability. Moreover, it becomes easier to uniformly generate the streamers 9 in the discharge space 3. Therefore, the uniformity of plasma density in the discharge space 3 can be improved. As a result, the plasma treatment can be uniformly performed.

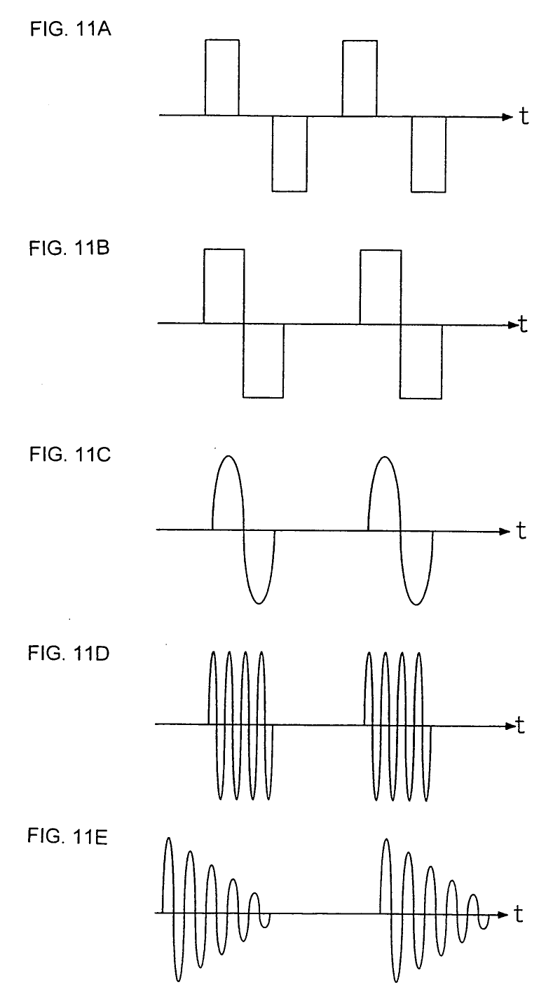

In addition, the waveform of the voltage applied between the electrodes 1, 2 can be a pulse-like waveform. The pulse-like waveform shown in FIG. 11A is obtained by giving a rest period every half period (half wavelength) in the waveform shown in FIG. 9A. The pulse-like waveform shown in FIG. 11B is obtained by giving a rest period every one period (one wavelength) in the waveform shown in FIG. 9A. The pulse-like waveform shown in FIG. 11C is obtained by giving a rest period every one period (one wavelength) in the waveform shown in FIG. 8A. The pulse-like waveform shown in FIG. 11D is obtained by giving a rest period every a plurality of periods in the waveform shown in FIG. 8A. The pulse-like waveform shown in FIG. 11E is obtained by giving a rest period every one repetition unit cycle in the waveform shown in FIG. 8D.

In the case of using the voltage of this pulse-like waveform, it is preferred that at least one of the rising and falling times is 100 μsec or less from the same reasons described above. In addition, it is preferred that the repetition frequency is in a range of 0.5 to 1000 kHz, and also the electric-field intensity is in a range of 0.5 to 200 kV/cm. This embodiment can provide the substantially same effects as the case of using the alternating voltage waveform with no rest period.

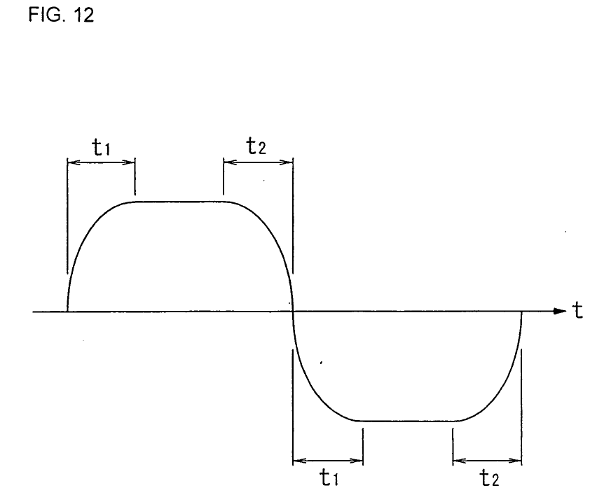

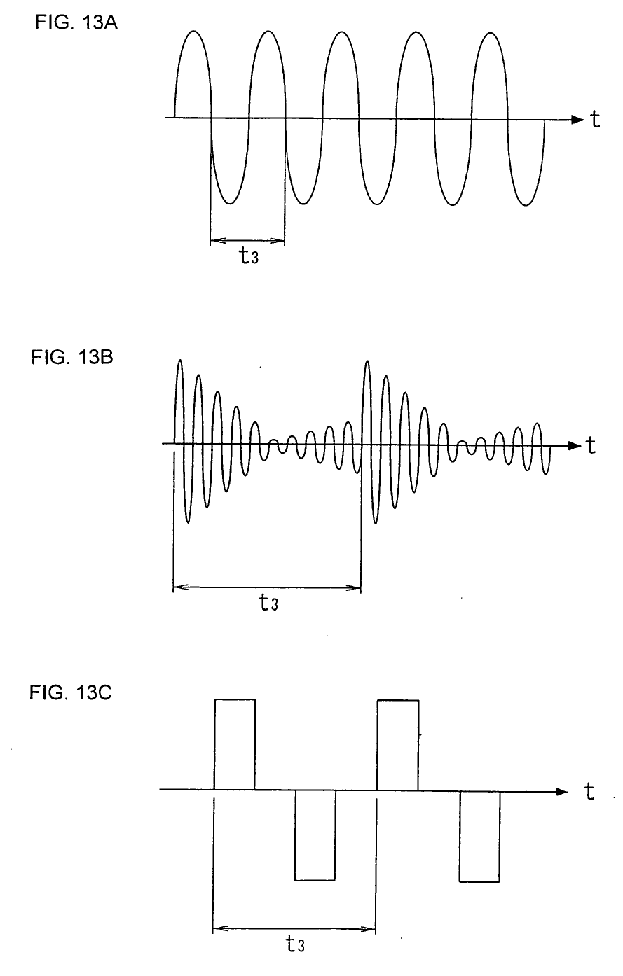

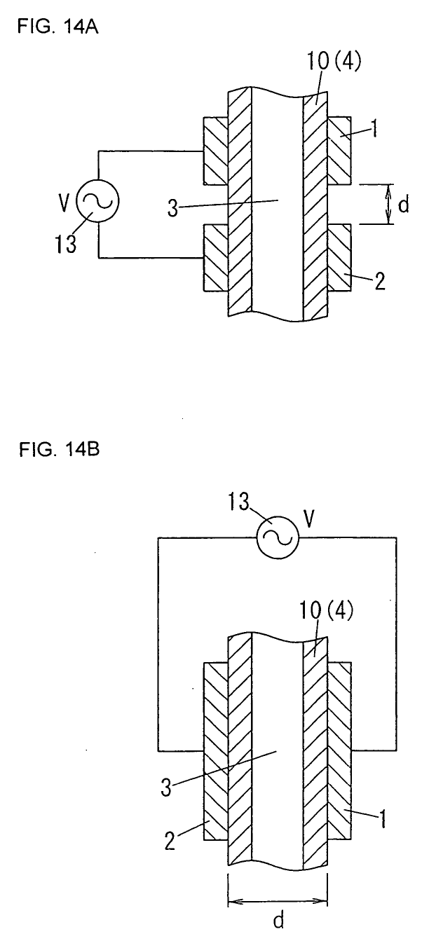

In the present invention, as shown in FIG. 12, the rising time is defined as a time period t₁ required to allow the voltage to reach the maximum value from zero cross of the voltage waveform, and the falling time is defined as a time period t₂ required to allow the voltage to reach the zero cross from the maximum value of the voltage waveform. In addition, as shown in FIG. 13A. FIG. 13B, an FIG. 13C, the repetition frequency in the present invention is defined as the inverse of the time period t₃ required for the repetition unit cycle. In the present invention, as shown in FIG. 14A and FIG. 14B, the electric-filed intensity is defined as (a voltage “V” applied between the electrodes 1, 2)/(a distance “d” between the electrodes). In FIG. 14A, the electrodes 1, 2 are disposed to face each other in the up and down direction. In FIG. 14B, the electrodes 1, 2 are disposed to face each other in the horizontal direction, as described later.

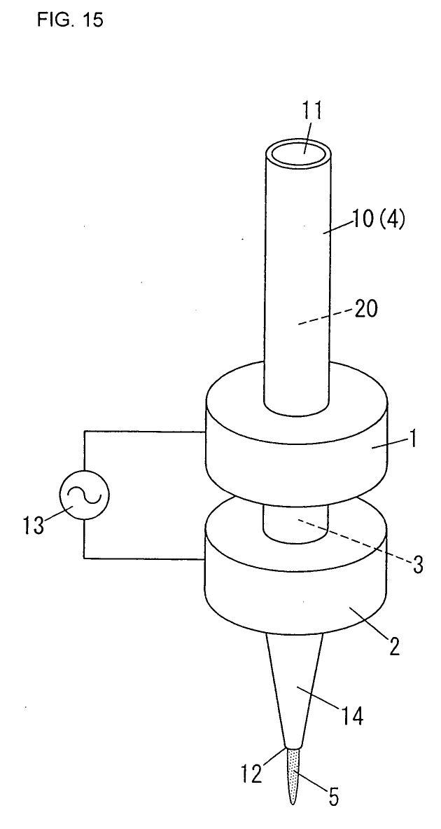

Another embodiment of the plasma treatment apparatus of the present invention is shown in FIG. 15. This apparatus is substantially the same as the apparatus of FIG. 1 except for forming a tapered nozzle portion 14 at the lower end of the reaction vessel 10 in the apparatus of FIG. 1. The nozzle portion 14 is formed such that its inner and outer diameters gradually decrease toward the lower end. The outlet 12 is opened over the entire surface of the lower end of the nozzle portion 14. The nozzle portion 14 of the reaction vessel 10 is positioned below the lower electrode 2. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

Since the plasma treatment apparatus of FIG. 15 has the nozzle portion 14, a flow velocity of the plasma 5 ejected from the outlet 12 becomes faster as compared with the apparatus of FIG. 1. As a result, it is possible to further improve the plasma treatment capability.

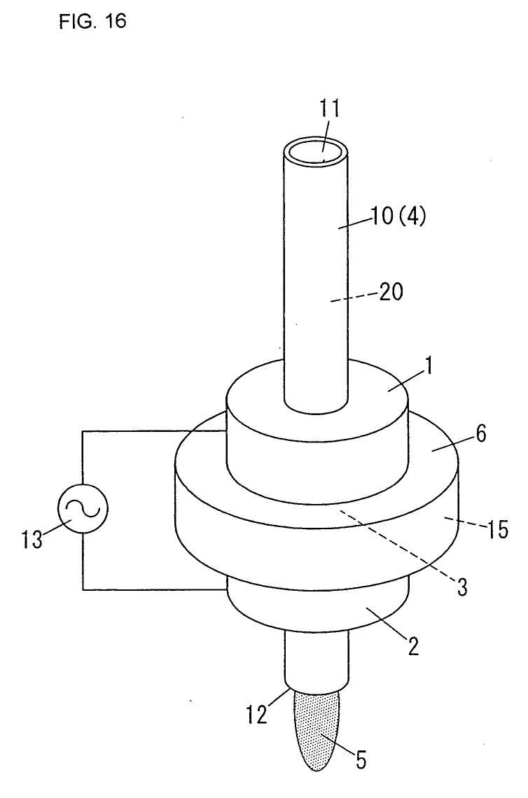

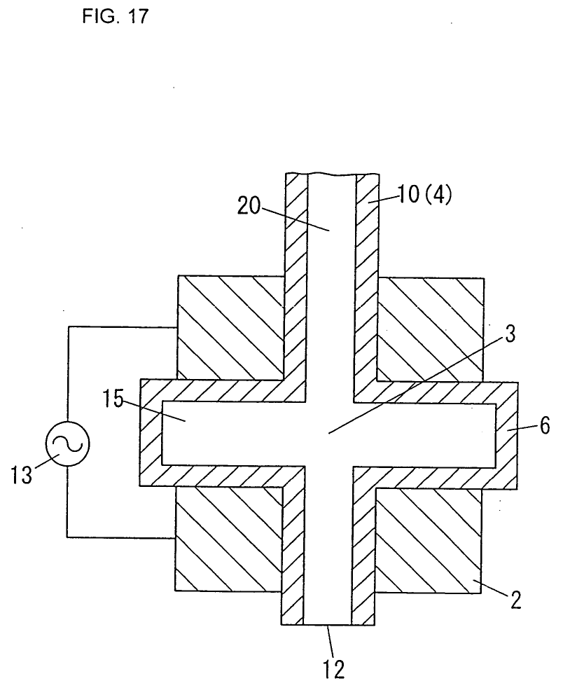

Another embodiment of the plasma treatment apparatus of the present invention is shown in FIG. 16. This apparatus is substantially the same as the apparatus of FIG. 1 except for forming a flange portion 6 of a dielectric material 4 between the electrodes 1, 2 in the apparatus of FIG. 1. The flange portion 6 is formed to extend over the entire outer circumference of the reaction vessel 10. In addition, the flange portion 6 is integrally formed with the reaction vessel 10 so as to project from the outer surface of the tubular portion of the reaction vessel into a space between the electrodes 1, 2. As shown in FIG. 17, most of the top surface of the flange portion 6 contacts the entire bottom surface of the upper electrode 1, and most of the bottom surface of the flange portion 6 contacts the entire top surface of the lower electrode 2. An inner space of the flange portion 6 communicating with the discharge space 3 provided by a part of the gas flow channel 20 is defined as a retention area 15. A part of the plasma generation gas supplied into the discharge space 3 can be temporarily held in this retention area 15. By applying the voltage between the electrodes 1, 2, a discharge is developed in this retention area 15 between the electrodes 1, 2 to generate a plasma 5. That is, the retention area 15 is included in the discharge space 3. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

Since the plasma treatment apparatus of FIG. 16 has the flange portion 6, all of the space between the opposed electrodes 1, 2 substantially becomes the discharge space (retention area 15), as compared with the apparatus of FIG. 1. Therefore, the occurrence of arc discharge outside the reaction vessel 10 and between the electrodes 1, 2 can be prevented. As a result, since the electric power applied between the electrodes is efficiently used for discharge, it is possible to generate the stable plasma. In addition, since the discharge between the opposed electrodes 1, 2 is obtained in the retention area 15, it is possible to reduce the discharge start voltage, and achieve the ignition of the plasma with reliability. Moreover, the plasma 5 generated in the retention area 15 is added to the plasma 5 generated in the discharge space 3 that is a part of the gas flow channel 20, and then a resultant plasma is ejected from the outlet 12. As a result, it is possible to further improve the plasma treatment performance as a whole.

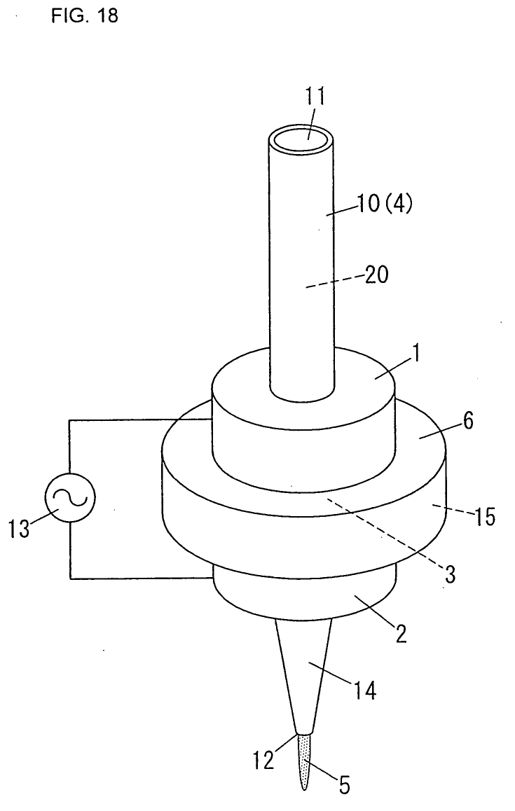

Another embodiment of the plasma treatment apparatus of the present invention is shown in FIG. 18. This apparatus is substantially the same as the apparatus of FIG. 15 except for forming a flange portion 6 in the apparatus of FIG. 15, as in the case of FIG. 16 or 17. The flange portion 6 shown in FIG. 18 provides the same effects as the above. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

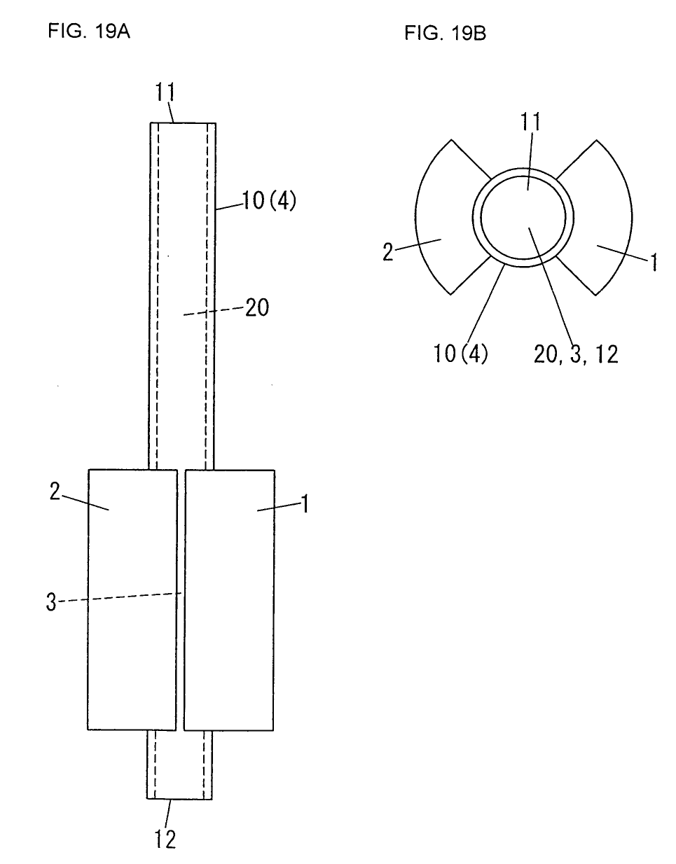

Another embodiment of the plasma treatment apparatus of the present invention is shown in FIGS. 19A and 19B. This apparatus is substantially the same as the apparatus of FIG. 1 except for changing the shape and arrangement of electrodes 1, 2 in the apparatus of FIG. 1. Each of the electrodes 1, 2 is formed to extend lengthwise in the up and down direction (parallel to the flow direction of the plasma generation gas) and such that the outer and inner peripheral surfaces are curved. The electrodes 1, 2 are disposed outside the reaction vessel 10 such that the inner curved surface of the respective electrode contacts the outer peripheral surface of the reaction vessel 10, and that the electrodes 1, 2 faces to each other in the substantially horizontal direction through the reaction vessel 10. An inner space of the reaction vessel 10 between the electrodes 1, 2 is defined as the discharge space 3. That is, a part of the gas flow channel 20 positioned between the electrodes 1, 2 is used as the discharge space 3. Therefore, a side wall of the reaction vessel 10 of the dielectric material 4 is positioned at the discharge-space side of the electrodes 1, 2. The discharge space 3 communicates with the gas inlet 11 and the outlet 12. The plasma generation gas flows in the gas flow channel 20 from the gas inlet 11 toward the outlet 12. Therefore, the electrodes 1, 2 are arranged side by side in a direction substantially orthogonal to the flow direction of the plasma generation gas in the gas flow channel 20. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

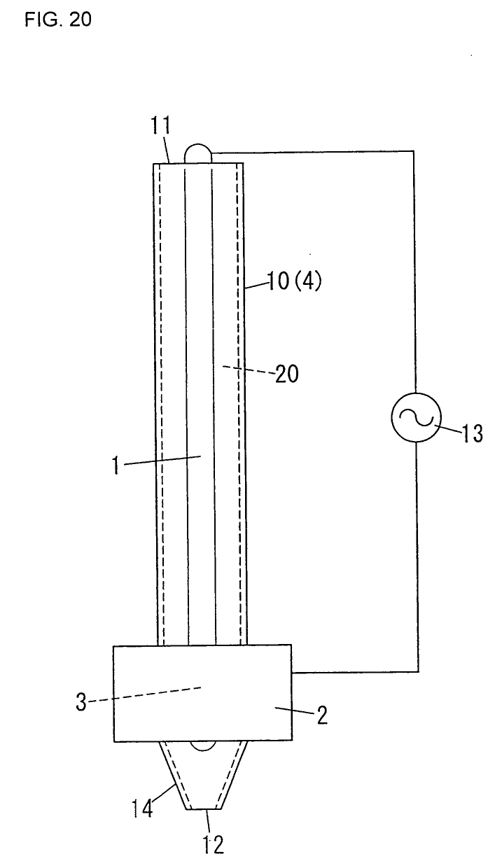

Another embodiment of the plasma treatment apparatus of the present invention is shown in FIG. 20. This apparatus is substantially the same as the apparatus of FIG. 1 except for changing the shape and arrangement of the electrodes 1, 2 in the apparatus of FIG. 15. The electrode 1 is formed in a long rod extending in the up and down direction (parallel to the flow direction of the plasma generation gas). The electrode 2 is formed in a doughnut shape, as described above. The electrode 1 is disposed in the gas flow channel 20 in the reaction vessel 10. The electrode 2 is placed outside the reaction vessel 10 to contact the outer peripheral surface of the reaction vessel 10 at the upper side of a tapered nozzle portion 14. Therefore, the electrode 1 faces to the electrode 2 in the horizontal direction through the side wall of the reaction vessel 10. An inner space of the reaction vessel 10 between the electrodes 1, 2 is defined as the discharge space 3. That is, a part of the gas flow channel 20 provided between the electrodes 1, 2 in the reaction vessel 10 is defined as the discharge space 3. Therefore, the side wall of the reaction vessel 10 of the dielectric material 4 is positioned at the discharge-space side of the electrode 2. The plasma generation gas flows in the gas flow channel 20 from the gas inlet 11 toward the outlet 12. The electrodes 1, 2 are arranged side by side in a direction substantially orthogonal to the flow direction of the plasma generation gas in the gas flow channel 20. A film of the dielectric material 4 may be formed on the outer surface of the electrode 1 by thermal spraying. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

Another embodiment of the plasma treatment apparatus of the present invention is shown in FIG. 21. This apparatus is substantially the same as the apparatus of FIG. 1 except for changing shapes of the reaction vessel 10 and the electrodes 1, 2.

The reaction vessel 10 is formed in a rectangular straight tube extending in the up and down direction, and also in a flat-plate shape that a length in a thickness direction orthogonal to a width direction on the horizontal plane is much smaller than the length in the width direction. In addition, an inner space of the reaction vessel 10 is defined as a long gas-flow channel 20 extending in the up and down direction. An upper end of the gas flow channel 20 is used as the gas inlet 11 opened over the entire top surface of the reaction vessel 10. A lower end of the gas flow channel 20 is used as the gas outlet 12 opened over the entire bottom surface of the reaction vessel 10. An inner size in the thickness direction (the short-length direction) of the reaction vessel 10 can be set in a range of 0.1 to 10 mm. However, the inner size is not limited to this range. Each of the outlet 12 and the gas inlet 11 is formed in a long slit extending in a direction parallel to the width direction of the reaction vessel 10.

The electrodes 1, 2 are formed in a rectangular frame by use of the same material described above. The electrodes 1, 2 are placed outside of the reaction vessel 10 such that an inner circumferential surface of the electrode contacts the outer circumferential surface of the reaction vessel 10 over the entire circumference thereof. In addition, the electrodes 1, 2 are arranged side by side to face each other in the longitudinal direction, i.e., the up-and-down direction of the reaction vessel 10. In the reaction vessel 10, a space between the top end of the upper electrode 1 and the bottom end of the lower electrode 2 is defined as a discharge space 3. That is, a part of the gas flow channel 20 therebetween is formed as the discharge space 3. Therefore, the side wall of the reaction vessel 10 of the dielectric material 4 is positioned at the discharge-space side of the electrodes 1, 2. The plasma generation gas flows in the gas flow channel 20 from the gas inlet 11 toward the outlet 12. Therefore, the electrodes 1, 2 are arranged side by side in a direction substantially parallel to the flow direction of the plasma generation gas in the gas flow channel 20. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1. According to the apparatuses shown in FIGS. 1 to 20, the plasma treatment can be locally performed by spraying the plasma 5 to the object surface in a spot-like manner. On the other hand, according to the apparatuses shown in FIG. 21 and the subsequent figures, the plasma treatment can be performed to a large area of the object surface at once by spraying the plasma 5 to the object surface in a band-like manner.

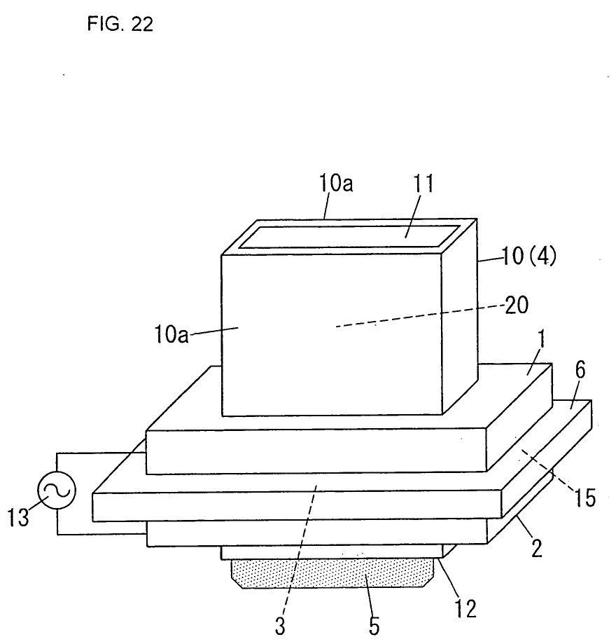

Another embodiment of the plasma treatment apparatus of the present invention is shown in FIG. 22. This apparatus is substantially the same as the apparatus of FIG. 21 except for forming a flange portion 6 in the apparatus of FIG. 21, as in the case of FIG. 16 or 17. The flange portion 6 shown in FIG. 22 provides the same effects as the above. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

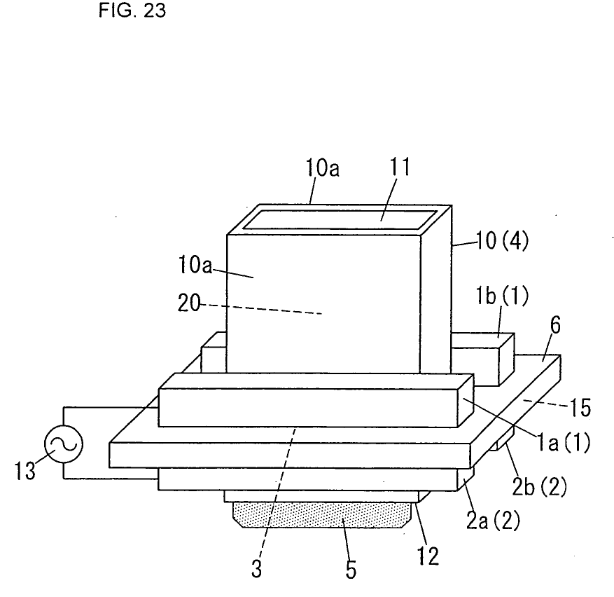

Another embodiment of the plasma treatment apparatus of the present invention is shown in FIG. 23. This apparatus is substantially the same as the apparatus of FIG. 22 except for changing the shape and arrangement of the electrodes 1, 2 in the apparatus of FIG. 22. A flange portion 6 shown in FIG. 23 provides the same effects as the above. The electrode 1 is formed by a pair of electrode members 1a, 1b each configured in a rectangular bar. The electrode 2 is formed by a pair of electrode members 2a, 2b each configured in the rectangular bar. Each of the electrode members (1a, 1b, 2a, 2b) is disposed such that its longitudinal direction is parallel to the width direction of the reaction vessel 10.

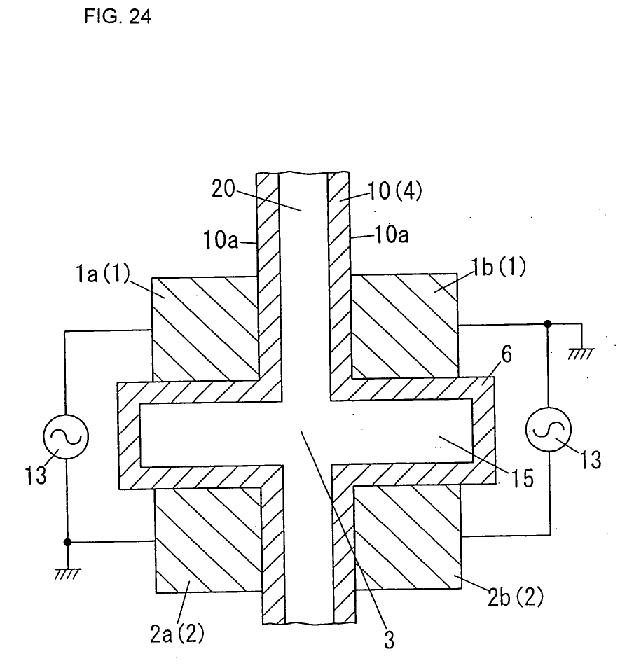

As shown in FIG. 24, the two electrode members 1a, 1b are disposed at both sides of the reaction vessel 10 on the flange portion 6 so as to face each other in the horizontal direction through the reaction vessel 10. The bottom surfaces of the electrode members 1a, 1b contact the top surface of the flange portion 6. Side surfaces of the electrode members 1a, 1b contact opposed side walls 10a of the reaction vessel 10. On the other hand, the other two electrode members 2a, 2b are disposed at both sides of the reaction vessel 10 on the flange portion 6 so as to face each other in the horizontal direction through the reaction vessel 10. The bottom surfaces of the electrode members 2a, 2b contact the bottom surface of the flange portion 6. Side surfaces of the electrode members 2a, 2b contact the opposed side walls 10a of the reaction vessel 10. The electrode members 1a, 2a are disposed to face each other in the up and down direction through the flange portion 6. Similarly, the electrode members 1b, 2b are disposed to face each other in the up and down direction through the flange portion 6.

The electrode members 1a, 2a are connected to a power source 13, as in the above case. Similarly, the other electrode members 1b, 2b are connected to another power source 13. The electrode members 1a, 2b are formed as high-voltage electrodes. On the other hand, the electrode members 1b, 2b are formed as low-voltage electrodes (ground electrode). With respect to the up and down direction, the opposed electrode members 1a, 2a and the opposed electrode members 1b, 2b are respectively arranged in substantially parallel to the flow direction of the plasma generation gas in the gas flow channel 20. With respect to the horizontal direction, the opposed electrode members 1a, 1b and the opposed electrode members 2a, 2b are respectively arranged in substantially orthogonal to the flow direction of the plasma generation gas in the gas flow channel 20. In the reaction vessel 10, a space surrounded by the electrode members 1a, 1b, 2a, 2b is defined as the discharge space 3. Therefore, the side walls and the flange portion 6 of the reaction vessel 10 of the dielectric material 4 are disposed at the discharge-space side of the electrode members 1a, 1b, 2a, 2b. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

Another embodiment of the plasma treatment apparatus of the present invention is shown in FIG. 25. This apparatus is substantially the same as the apparatus of FIG. 21 except for changing the shape of the gas inlet 11 and the shape and arrangement of the electrodes 1, 2 in the apparatus of FIG. 21. The gas inlet 11 is positioned at a substantially center of the top surface of the reaction vessel 10, and formed in a long slit shape extending in a direction parallel to the width direction of the reaction vessel 10.

The electrodes 1, 2 are formed in a planar shape by use of the same metal material described above. In addition, those electrodes 1, 2 are disposed to contact the outer surfaces of opposed side walls 10a in the thickness direction of the reaction vessel 10. Therefore, the electrodes extend in parallel through the reaction vessel 10. In the reaction vessel 10, a region between the electrodes 1, 2 is defined as the discharge space 3. That is, a part of the gas flow channel 20 positioned between the electrodes is used as the discharge space 3. In addition, the side walls 10a of the reaction vessel 10 made of the dielectric material 4 are positioned at the discharge-space side of the both electrodes 1, 2. The plasma generation gas flows in the gas flow channel 20 from the gas inlet 11 toward the outlet 12. Therefore, the electrodes 1, 2 are arranged side by side in a direction substantially orthogonal to the flow direction of the plasma generation gas in the gas flow channel 20. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

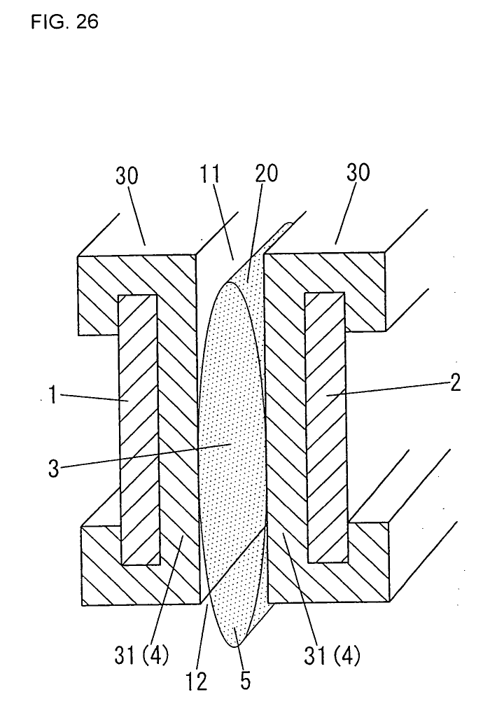

Another embodiment of the plasma treatment apparatus of the present invention is shown in FIG. 26. This apparatus is formed with a pair of electrode bodies 30. The electrode body 30 is composed of a planar electrode 1(2) made of the metal material described above and a cover 31 made of the dielectric material described above. The cover 31 can be formed on the electrode 1(2) by thermal spraying of the dielectric material 4 to cover the front surface, top end surface, bottom end surface, and a part of the rear surface of the electrode 1(2).

The pair of electrode bodies 30 are disposed to face each other through a clearance. In addition, the electrodes are connected to a power source, as in the above case. At this time, a planar direction of the electrodes 1, 2 is in agreement with the up and down direction, and the electrodes are disposed to extend in parallel. In addition, the front surfaces coated by the cover 31 of the electrode bodies 30 face each other. The clearance between the opposed electrode bodies 30 is formed as the gas flow channel 20. A region of the gas flow channel 20 between the opposed electrodes 1, 2 is defined as the discharge space 3. That is, a part of the gas flow channel 20 provided between the electrodes 1, 2 is used as the discharge space 3. Thus, the cover 31 made of the dielectric material 4 is positioned at the discharge-space side of the electrodes 1, 2. A top end of the gas flow channel 20 is opened as the gas inlet 11, and a bottom end of the gas flow channel 20 is opened as the outlet 12. The discharge space 3 communicates with the gas inlet 11 and the outlet 12. The plasma generation gas flows in the gas flow channel 20 from the gas inlet 11 toward the outlet 12. Therefore, the electrodes 1, 2 are arranged side by side in a direction substantially orthogonal to the flow direction of the plasma generation gas in the gas flow channel 20. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

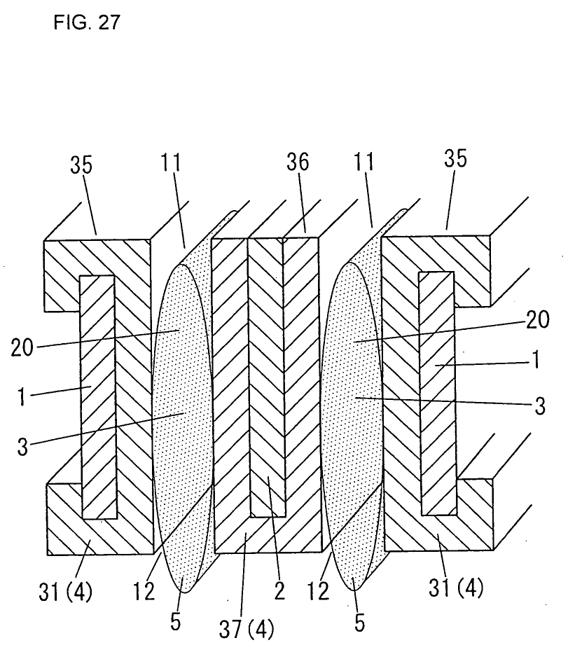

Another embodiment of the plasma treatment apparatus of the present invention is shown in FIG. 27. This apparatus is formed with a pair of side electrode bodies 35 and a center electrode body 36. The side electrode body 35 is composed of a planar electrode 1 and a cover 31 made of the dielectric material 4, as in the case of the electrode body 30 described above. The cover 31 can be formed on the electrode 1(2) by thermal spraying of the dielectric material 4 to cover the front surface, top end surface, bottom end surface, and a part of the rear surface of the electrode 1. The center electrode body 36 is composed of a planar electrode 2 made of the metal material described above and a cover 37 made of the dielectric material 4 described above. The cover 37 can be formed on the electrode 2 by thermal spraying of the dielectric material 4 to cover opposite planar surfaces and a bottom end surface of the electrode 2.

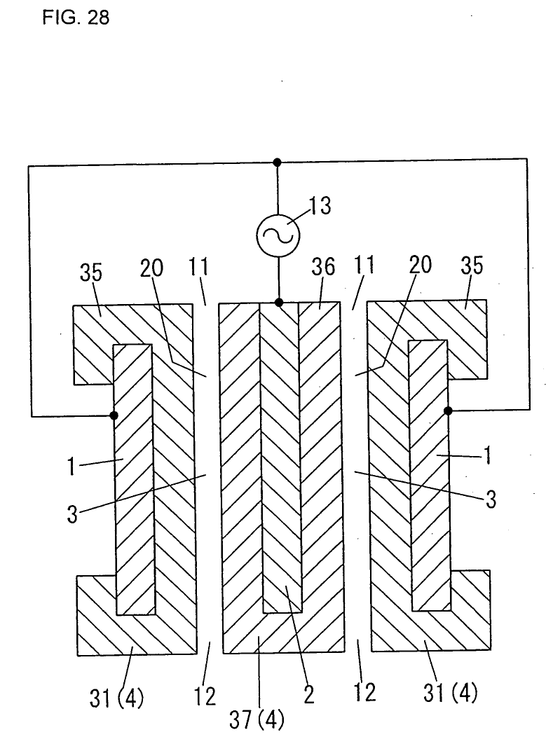

The pair of the side electrode bodies 35 is arranged to face each other through a clearance, and the center electrode body 36 is placed between the side electrode bodies such that a clearance is provided between the center electrode body and each of the side electrode bodies. As shown in FIG. 28, a power source 13 is connected to the electrodes 1, 2. At this time, the planar direction of the electrode 1, 2 is in agreement with the up and down direction, and the electrodes 1, 2 are disposed in parallel. A front surface coated with the cover 31 of the side electrode body 35 faces the center electrode body 36. The clearance between the center electrode body 36 and each of the side electrode bodies 35 is formed as the gas flow channel 20. A region between the electrodes 1, 2 of the gas flow channel 20 is defined as the discharge space 3. That is, a part of the gas flow channel 20 positioned between the electrodes 1, 2 is used as the discharge space 3. Therefore, the covers 31, 37 of the dielectric material 4 are formed at the discharge-space side of the electrodes 1, 2. An upper end of the gas flow channel 20 is opened as the gas inlet 11, and a lower end of the gas flow channel 20 is opened as the gas outlet 12. The discharge space 3 communicates with the gas inlet 11 and the outlet 12. The plasma generation gas flows in the gas flow channel 20 from the gas inlet 11 toward the outlet 12. The electrodes 1, 2 are arranged side by side in a direction substantially orthogonal to the flow direction of the plasma generation gas in the gas flow channel 20. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1. By the way, this plasma treatment apparatus has a plurality (two) of discharge spaces 3 for generating the plasma 5. Therefore, it is possible to increase the number of objects to be treated by the plasma at once, and improve the plasma treatment efficiency.

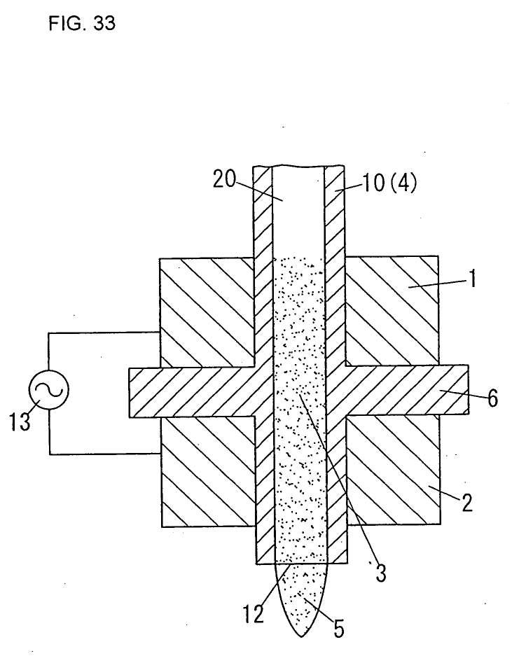

Another embodiment of the plasma treatment apparatus of the present invention is shown in FIG. 33. This apparatus is substantially the same as the apparatus of FIG. 1 except for forming a flange portion 6 of a dielectric material 4 between the electrodes 1, 2 in the apparatus of FIG. 1. Therefore, the visual appearance of the plasma treatment apparatus of FIG. 33 is the same as that of FIG. 16. The flange portion 6 is formed to extend over the entire outer circumference of the reaction vessel 10. In addition, the flange portion 6 is integrally formed with the reaction vessel 10 so as to project from the outer surface of the tubular portion of the reaction vessel into a space between the electrodes 1, 2. Most of the top surface of the flange portion 6 contacts the entire bottom surface of the upper electrode 1, and most of the bottom surface of the flange portion 6 contacts the entire top surface of the lower electrode 2. In this embodiment, there is no room in the flange portion 6. That is, since the flange portion 6 is filled with the dielectric material 4, it does not have the hollow structure such as the retention area 15 shown in FIG. 16. Thus, the plasma treatment apparatus of FIG. 33 is substantially the same as the apparatus of FIG. 16 except that the retention area 15 is not formed. Therefore, it is possible to easily produce the reaction vessel 10, as compared with the apparatus of FIG. 16. In addition, as in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

In the plasma treatment apparatus of the patent document 1 mentioned above, an electric power applied to the discharge space for the dielectric barrier discharge can be determined by multiplying the electric power of one cycle by the frequency. In the case of using the high-frequency voltage of 13.56 MHz to develop the discharge, even if the electric power of one cycle is small, the frequency is high. As a result, the electric-power value becomes large as a whole. To obtain the applied electric power equivalent to 13.56 MHz under a condition that the frequency of the voltage applied between the electrodes (the frequency of the voltage required to perform the ignition of the plasma) is small, it is needed to increase the electric power per one cycle. To realize this, it is needed to increase the voltage applied to the electrodes. In the case of using 13.56 MHz, the voltage applied between the electrodes is approximately 2 kV at the maximum. Therefore, a probability of causing dielectric breakdown between the electrodes and outside the reaction vessel is extremely low. On the contrary, in the case of lowering the frequency of the voltage applied between the electrodes 1, 2, it is needed that the voltage applied between the electrodes 1, 2 is 6 kV or more although it changes depending on the frequency used. Therefore, the probability of causing the dielectric breakdown between the electrodes 1, 2 and outside the reaction vessel 10 becomes high. When the dielectric breakdown occurs, the plasma 5 is not obtained at the discharge space 3 in the reaction vessel 10. As a result, there causes a problem that the plasma treatment apparatus does not normally operate to provide the plasma treatment. That is, to lower the frequency of the voltage applied between the electrodes 1, 2, it is needed to increase the voltage applied between the electrodes. As a result, there is a probability that the dielectric breakdown is caused between the electrodes 1, 2 and outside the reaction vessel 10.

In the plasma treatment apparatus of FIG. 33, since the flange portion 6 is formed outside the reaction vessel 10 and between the electrodes 1, 2, it is possible to prevent a situation that dielectric breakdown directly occurs outside of the reaction vessel 10 and between the electrodes 1, 2, and stably perform the ignition of the plasma 5 at the discharge space 3 in the reaction vessel 10. As a result, the plasma treatment apparatus can be operated with reliability to perform the plasma treatment.

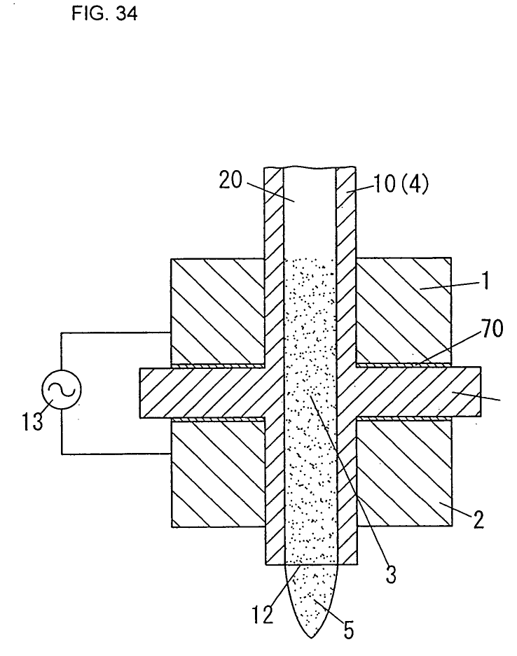

Another embodiment of the plasma treatment apparatus of the present invention is shown in FIG. 34. This apparatus is substantially the same as the apparatus of FIG. 33 except that a filler 70 is filled in a clearance between the electrode 1, 2 and the flange portion 6 in the apparatus of FIG. 33 to intimately contact the electrodes 1, 2 with the flange portion 6 through the filler. That is, by filling the filler 70 in the clearance between the bottom surface of the upper electrode 1 and the top surface of the flange portion and the clearance between the top surface of the lower electrode 2 and the bottom surface of the flange portion 6, it is possible to bring the electrodes 1, 2 into intimate contact with the flange portion through the filler 70 filled in those clearances. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

In the present invention, since the reaction vessel 10 (including the flange portion 6) is made of the dielectric material such as glass, it is difficult to obtain unrelieved flat surface of the flange portion. Therefore, there is a case that a clearance occurs between the flange portion 6 and the electrode 1, 2. In such a case, corona discharge may occur at the clearance because the voltage applied between the electrodes is high. When the electrodes are exposed to the corona discharge, it may lead to corrosion of the electrodes and consequently a reduction in lifetime

The occurrence of corona discharge in the clearance between the flange portion 6 and the electrode 1, 2 can be prevented by intimately contacting the flange portion 6 with the electrodes 1, 2. However, as described above, when the flange portion 6 has a bumpy surface, it is difficult to mechanically fit the flange portion to the electrodes. Therefore, by filling a filling material 70 in the clearance between the electrode 1, 2 and the flange portion 6, the clearance can be perfectly sealed to prevent the corrosion of the electrodes 1, 2 and extend the lifetime of the electrodes. As the filling material 70, an adhesive material having a certain degree of viscosity such as grease and a binding material or a flexible sheet material such as rubber sheet can be used.

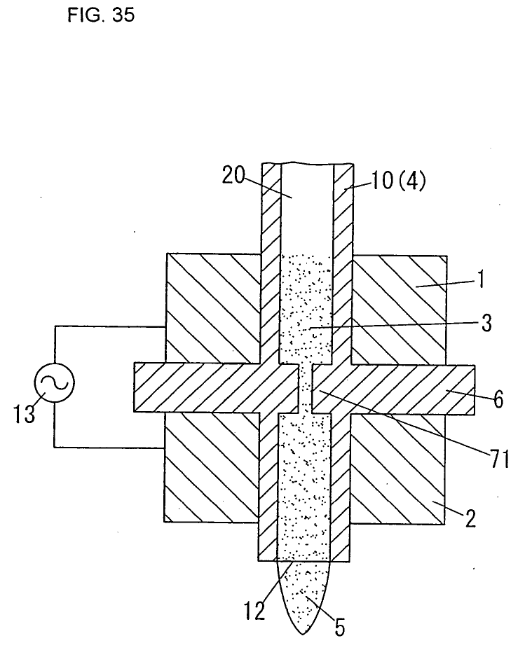

Another embodiment of the plasma treatment apparatus of the present invention is shown in FIG. 35. This apparatus is substantially the same as the apparatus of FIG. 33 except for are partially narrowing the discharge space 3 between the electrodes 1, 2 in the apparatus of FIG. 33. That is, a projecting portion 71 is formed over the entire circumference of the reaction vessel on the inner surface of the reaction vessel 10 at a position corresponding to the flange portion 6. The size of the discharge space 3 at the projecting portion 71 (i.e., the inner diameter at the projection portion 71) is smaller than the size of the discharge space at a portion other than the projecting portion 71 (i.e., the inner diameter of the reaction vessel 10). In addition, the projecting portion 71 is formed to have substantially the same thickness as the flange portion 6. The narrow region of the discharge space 3 is positioned at substantially the center of the discharge space 3 in the up and down direction. In this plasma treatment apparatus, the filling material 70 described above may be used. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1.

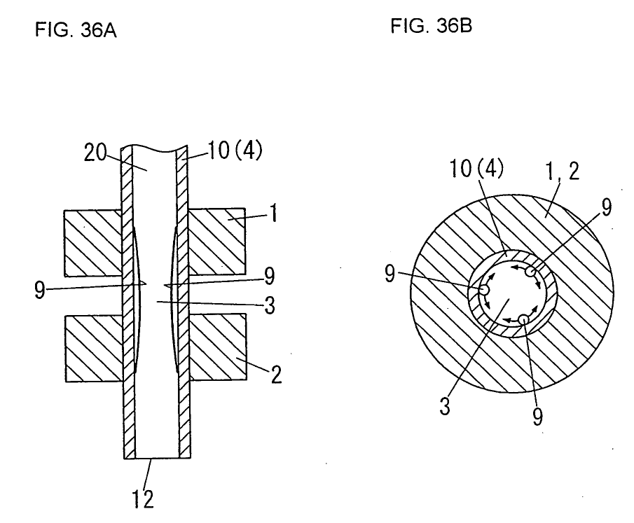

As shown in FIGS. 36A and 36B, in the case of using the reaction vessel 10 without the projecting portion 71, the dielectric barrier discharge developed by a low-frequency voltage is a discharge, in which streamers 9 are generated in the discharge space 3 so as to contact the inner surface of the reaction vessel 10. Since the streamers are not stable with respect to time, they move around (run around) the inner surface of the reaction vessel 10 in the circumferential direction. Therefore, the plasma 5 ejected in the jet-like manner from the outlet 12 of the reaction vessel 10 shakes in synchronism with the motions of the streamers 9. As a result, variations in the plasma treatment on the object may occur.

In this embodiment, the discharge space 3 is partially narrowed by forming the projecting portion 71 to limit the space that the streamers 9 can run around the inner surface of the reaction vessel 10. As a result, it is possible to prevent a situation that the plasma 5 is ejected in the jet-like manner from the outlet 12, while shaking, and therefore minimize variations in the plasma treatment.

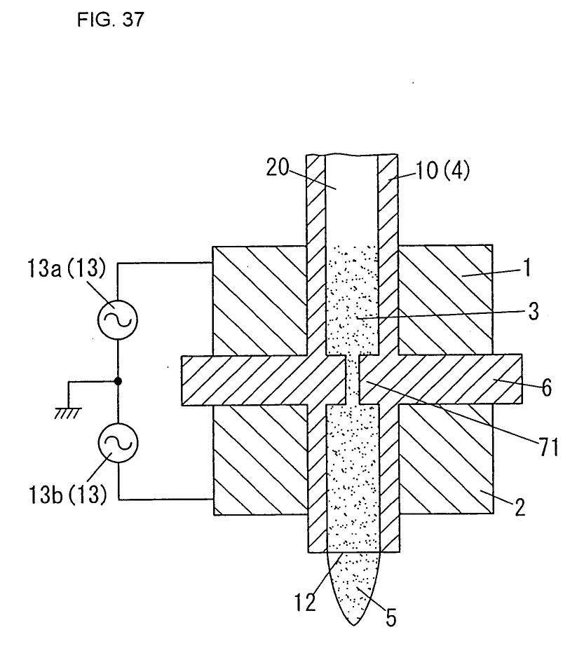

Another embodiment of the plasma treatment apparatus of the present invention is shown in FIG. 37. This apparatus is substantially the same as the apparatus of FIG. 35 except for applying a voltage such that both of the electrodes 1, 2 are in a floating state with respect to the ground potential in the apparatus of FIG. 33. That is, the electrodes 1, 2 are respectively connected to individual power sources 13a, 13b to be placed in the floating state with respect to the ground. Thereby, electric powers can be applied to the electrodes 1, 2 from the power sources 13a, 13b in the floating state. As in the case of FIG. 1, this apparatus has the capability of generating plasma 5 to perform the plasma treatment. Therefore, the composition of the plasma generation gas as well as the waveform and the electric field intensity of the voltage applied between the electrodes 1, 2 are substantially the same as the case of FIG. 1. The power sources 13a, 13b can be provided by a single power-source device. Alternatively, they may be composed of a plurality of power-source devices.

When lowering the repetition frequency of the voltage applied between the electrodes 1, 2, it is needed to increase the voltage applied between the electrodes 1, 2. The increase in the voltage applied between the electrodes 1, 2 leads to an increase in electric potential of the plasma 5 generated at the discharge space 3 in the reaction vessel 10. In this case, since a voltage difference between the plasma 5 and the object (usually grounded) becomes large, dielectric breakdown (arc discharge) may occur therebetween. In this embodiment, to prevent the occurrence of dielectric breakdown between the plasma 5 and the object, both of the electrodes 1, 2 are placed in a floating state with respect to the ground potential. In this case, even if the voltage value applied between the electrodes 1, 2 is the same as that applied in the other embodiments, it is possible to reduce the voltage of the plasma 5 with respect to the ground, and prevent the occurrence of dielectric breakdown between the plasma 5 and the object. As a result, it is possible to avoid a situation that arc discharge is developed therebetween, and the object receives damages by the arc discharge.

In the present invention, as shown by the embodiments of FIGS. 1, 15 to 18, 21 to 24 and 33 to 37, the electrodes 1, 2 are arranged side by side in a (up and down) direction substantially parallel to the flow direction of the plasma generation gas in the gas flow channel 20 such that an electric field is developed in the direction substantially parallel to the flow direction of the plasma generation gas in the discharge space 3 by applying the voltage between the electrodes 1, 2. In this case, since the current density of streamers 9 generated in the discharge space 3 increases, the plasma density increases. As a result, the plasma treatment performance can be improved.

On the other hand, as shown by the embodiments of FIGS. 19, 20 and 23 to 28, when the electrodes 1, 2 are arranged side by side in a (horizontal) direction substantially orthogonal to the flow direction of the plasma generation gas flowing in the gas flow channel 20, an electric field is developed in the direction substantially orthogonal to the flow direction of the plasma generation gas in the discharge space 3 by applying the voltage between the electrodes 1, 2, so that streamers are uniformly generated in the electrode surfaces. Thus, since the streamers 9 are uniformly generated in the discharge space 3, the uniformity of the plasma treatment can be improved.

In the plasma treatment apparatus shown in FIGS. 23 and 24, both of the generation of the streamers 9 having a high plasma density and the uniform distribution of the streamers 9 in the discharge space 3 can be achieved. Therefore, it is possible to improve both of the plasma treatment performance and the uniformity of the plasma treatment.

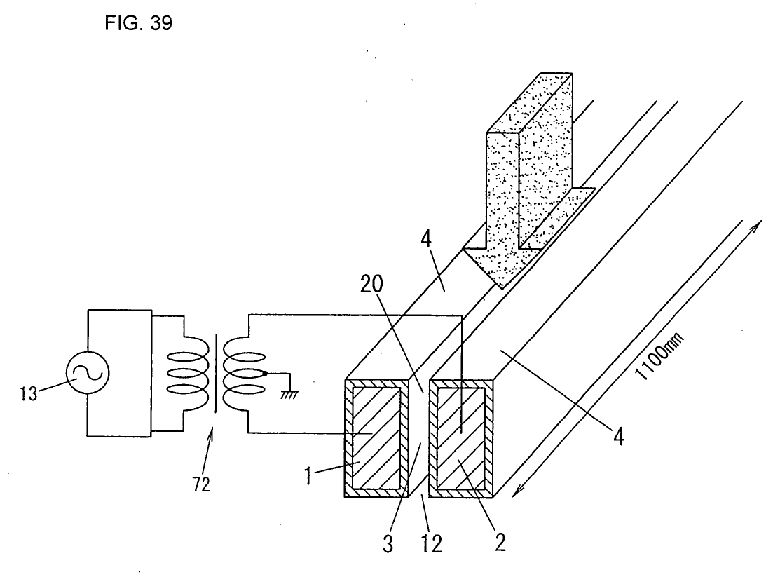

Another embodiment of the plasma treatment apparatus of the present invention is shown in FIG. 39. This apparatus is provided with a pair of electrodes 1, 2. A dielectric material 4 is formed on the electrode surface 1, 2 by thermal spraying of a ceramic material such as alumina, titania or zirconia. In this case, it is preferred to perform a sealing treatment. As a sealing material, it is possible to use an organic material such as epoxy or an inorganic material such as silica. Alternatively, enamel coating may be performed by use of an inorganic glaze material such as silica, titania, alumina, tin oxide or zirconia. In the case of using the thermal spraying or the enamel coating, it is possible to set the thickness of the dielectric material in a range of 0.1 to 3 mm, and preferably 0.3 to 1.5 mm. When the thickness is smaller than 0.1 mm, dielectric breakdown of the dielectric material may occurs. When the thickness is larger than 3 mm, it is hard to apply the voltage to the discharge space, so that the discharge becomes unstable. In addition, as in the case of FIG. 37, the voltage is applied to the electrodes 1, 2 in the floating state with respect to the ground. Other configurations are substantially the same as another embodiments described above.

Moreover, in the present invention, when exposing the object to the plasma jet to perform the plasma treatment, a reaction that happens on the object's surface is a chemical reaction. Therefore, as the reaction temperature increases, the reaction speed becomes faster. Due to this reason, it is preferred to previously heat the plasma generation gas or heat the object. As a result, an improved plasma treatment speed is obtained.

In the present invention, when using the reaction vessel 10 having a large width, it is effective to use a means of keeping the distance between the electrodes 1, 2 constant and a means (air nozzle) of ejecting the gas uniformly in the width direction for the purpose of ensuring the uniformity of treatment in the width direction.

Additionally, in the present invention, when performing the plasma treatment to the object placed under the outlet 12, while conveying the object in one direction, it is preferred that the direction of ejecting the plasma 5 from the outlet 12 is inclined toward the (forward) direction of conveying the object such that the plasma ejecting direction is not orthogonal to the conveying direction. Thereby, the plasma 5 provided from the outlet 12 can be sprayed on the object surface, while sucking the air existing between the outlet 12 and the object. As a result, excited species generated in the plasma 5 collide with oxygen molecules in the air to dissociate oxygen. Since the dissociated oxygen modifies the object surface, the plasma treatment capability can be improved.

It is preferred to that the ejecting direction of the plasma 5 from the outlet 12 is inclined at 2 to 6 degrees with respect to the conveying direction of the object. However, it is not limited to this range.

The nitrogen gas may be supplied from a nitrogen gas generator for separating and purifying nitrogen from the air. In this case, the membrane separation process or the PSA (pressure swing adsorption) method can be used as the purifying method.

To improve the plasma treatment performance, it is needed to increase the frequency of the voltage applied to generate the plasma. In such a condition, when a flow velocity of the plasma generation gas ejected from the outlet 12 in a non-discharge state is less than 2 m/sec, glow-like uniform discharge disappears, and a streamer-like discharge occurs. When the discharge is kept under this condition, abnormal discharge (arc discharge) occurs. In the present invention, when the flow velocity of the plasma generation gas ejected from the outlet 12 in the non-discharge state is in a range of 2 m/sec to 100 m/sec, the streamers are constricted, so that infinite number of fine filament-like discharges occur. As a result, an extremely high treatment effect can be realized by modifying the discharge state. When the flow velocity is more than 100 m/sec, the gas temperature lowers, so that the modifying effect deteriorates. In the present invention, the gas flow amount of the plasma generation gas supplied into the discharge space 3 can be regulated to set the flow velocity in the range of 2 to 100 m/sec.

### EXAMPLES

The present invention is specifically explained below according to Examples.

### Examples 1-5

A plasma treatment apparatus for spot treatment shown in FIG. 16 was used. A reaction vessel 10 of this plasma treatment apparatus is of a quartz pipe having the inner diameter of 3 mm and the outer diameter of 5 mm, which is provided with a hollow flange portion 6 (retention area 15) having the outer diameter of 50 mm. Electrodes 1, 2 and the flange portion 6 are arranged so as to have the cross-sectional structure shown-in FIG. 17.

A plasma generation gas was supplied into a gas flow channel 20 from an gas inlet 11 of the reaction vessel 10, and a plasma was generated by a voltage supplied from a power source 13 connected to the electrode 1 of the upstream side and the electrode 2 of the downstream side. The plasma 5 was ejected from an outlet 12. By exposing an object placed at the downstream side of the outlet 12 to the plasma, the plasma treatment was carried out. As the plasma generation gas, a mixture of argon and oxygen was used. Other conditions of generating the plasma are shown in Table 2.

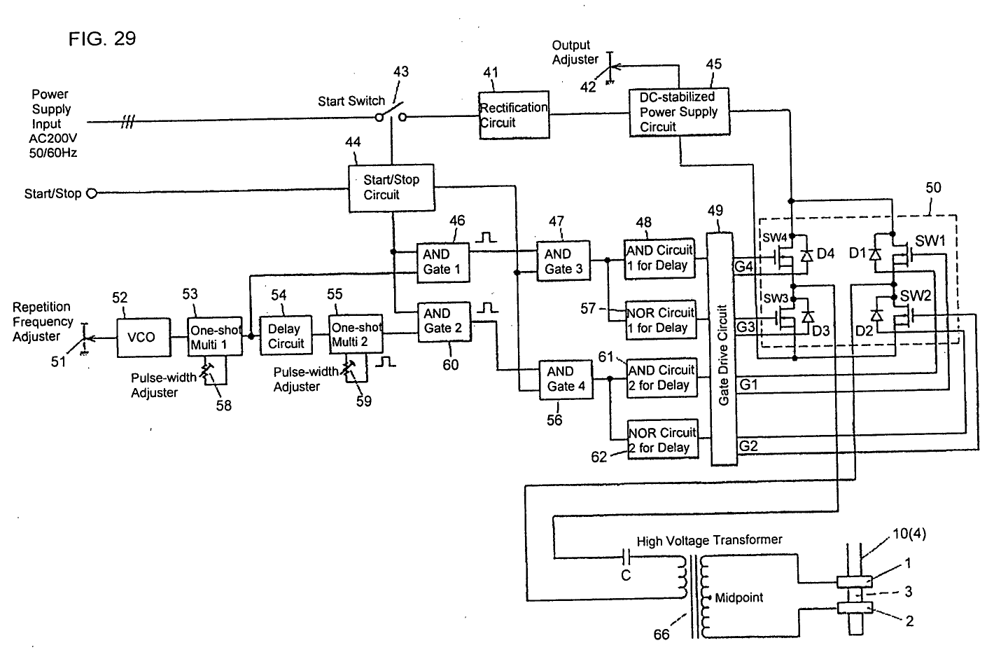

Here, as a preferred embodiment, the power source 13 used in the examples is explained. The power source 13 of Example 4 has a circuit shown in FIG. 29.

In the circuit of FIG. 29, an H-bridge switching circuit (inverter) 50 for generating positive and negative pulses applied to the primary side of a high-voltage transformer 66 is firstly explained. As shown in FIG. 29, this H-bridge switching circuit 50 has first, second, third and fourth semiconductor switching devices (SW1, SW2, SW3, SW4), which are connected in an H-bridge manner such that SW1, SW4 are upper arms, SW2 is a lower arm for SW1, and SW3 is a lower arm for SW4 (the H-bridge is formed by use of semiconductor module including two of MOS-FET and so on). In addition, the switching circuit comprises diodes (D1, D2, D3, D4), each of which is connected in parallel to the corresponding switching device. As an power source for the H-bridge switching circuit 50, a DC power source can be used, which comprises a rectification circuit 41 for rectifying a voltage having the commercial power frequency and a DC-stabilized power supply circuit 45. An output voltage of the DC-stabilized power supply circuit 45 can be adjusted by an output adjuster 42.

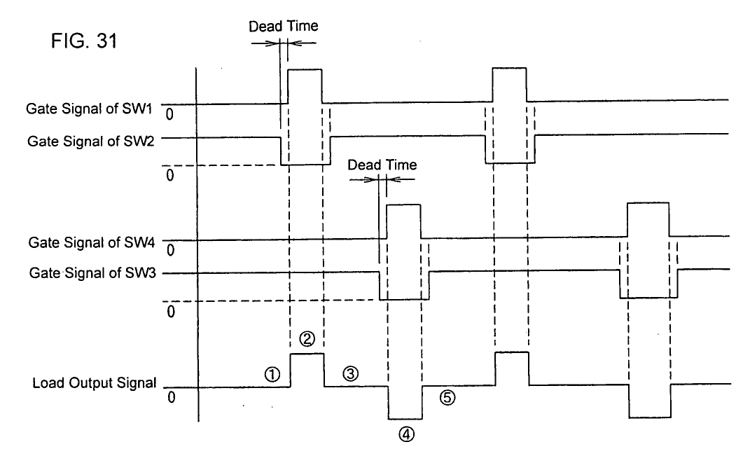

This H-bridge switching circuit 50 is repeatedly operated in a combination manner of five ON/OFF operations of \mathring{1}, \mathring{2}, \mathring{3}, \mathring{4}, \mathring{5} shown in Table 1 by use of a gate drive circuit 49 and the preliminary circuits. FIG. 31 is a timing chart of positive and negative alternated pulses output from mid points between the first and second switching devices SW1, SW2 and between the third and fourth switching devices SW3, SW4.

TABLE 1

| | \mathring{1} | \mathring{2} | \mathring{3} | \mathring{4} | \mathring{5} |
|---|---|---|---|---|---|
| SW1 | OFF | ON | OFF | OFF | OFF |
| SW2 | ON | OFF | ON | ON | ON |
| SW3 | ON | ON | ON | OFF | ON |
| SW4 | OFF | OFF | OFF | ON | OFF |
| D2 | OFF | OFF | OFF | OFF | ON |
| D3 | OFF | OFF | ON | OFF | OFF |

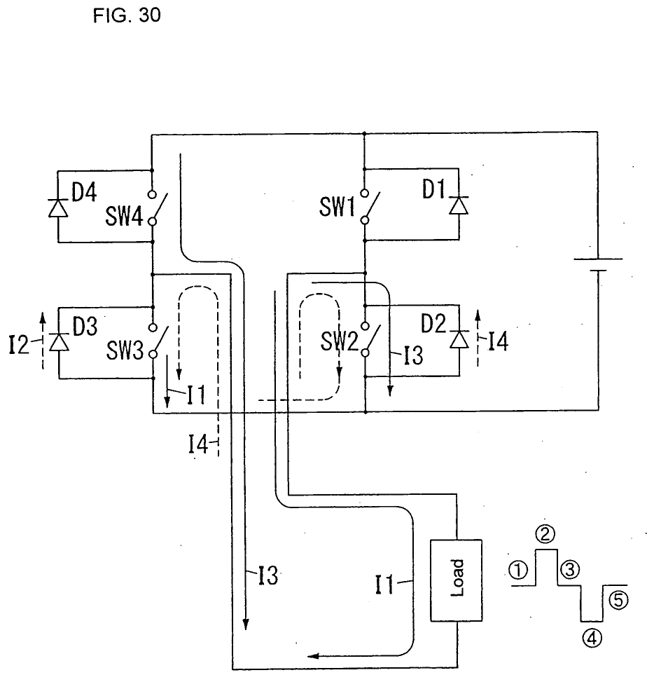

FIG. 30 shows an equivalent circuit of the H-bridge switching circuit 50. As shown in FIG. 31, a time width at the time of turning off the second switching device SW2 is longer in the forward and rearward directions than the time width at the time of turning on the first switching device SW1. In addition, a time width at the time of turning off the third switching device SW3 is longer in the forward and rearward directions than the time width at the time of turning on the fourth switching device SW4.

In FIG. 30, when SW1 is turned on after SW1 is turned off, electric current flows in the direction of “I1”, so that the load is positively charged. Next, when SW2 is turned on after SW1 is turned off, electric current flows in the direction of “I2” through SW2 and D3, so that stray capacitance and leakage inductance of the load are forcedly reset by SW2 and D3.

Subsequently, when SW4 is turned on after SW3 is turned off, electric current flows in the direction of “I3”, so that the load is negatively charged. Next, when SW4 is turned on after SW3 is turned off, electric current flows in the direction of “I4”, so that leakage inductance and stray capacitance of the load are forcedly reset by SW2 and D3.

These operations are explained according to Table 1.

In \mathring{1}, SW2 and SW3 are turned on by the input of a gate signal, so that both ends of the load become in a short-circuit state.

In \mathring{2}, when the gate signal of SW2 is turned off, and after a small delay SW1 is turned on by the input of the gate signal, electric current flows in the direction of “I1” from SW1 through the load because SW3 is maintained in the ON state. As a result, the load is positively charged.

In \mathring{3}, after inputting the gate signal to SW1 is finished, and SW1 is turned off, the gate signal is input to SW2 again to turn on SW2. Electric charges stored in the load are discharged through SW2 and D3. As a result, it returns to the same state as \mathring{1}.

In \mathring{4}, when SW3 is turned off, and after a small delay the gate signal is input to SW4 to turn on SW4, electric current flows in the direction of “I3” from SW4 through the load because SW2 is maintained in the ON state. As a result, the load is negatively charged.

In \mathring{5} after inputting the gate signal to SW4 is finished, and SW4 is turned off, the gate signal is input to SW3 again to turn on SW3. Electric charges stored in the load are discharged through SW3 and D2. As a result, it returns to the same state as \mathring{3}.

Thus, when the switching operation is performed in the order of \mathring{1} to \mathring{5} by giving a dead time such that the set of SW1 and SW2 are not simultaneously turned on, and the set of SW3 and SW4 are not simultaneously turned on, an output signal (a pair of positive and negative pulses spaced from each other by a certain time) having a waveform in proportion to the input signal (gate signal) is obtained. In this case, since the leakage inductance and the stray capacitance of the load are rest by the above switching operations, it is possible to obtain the output waveform with no strain.

In FIG. 29, the output of the H-bridge switching circuit 50 obtained by the switching operations described above is provided such that the mid point between the first and second switching devices SW1, SW2 is one polarity and the mid point between the third and fourth switching devices SW3, SW4 is the other polarity, and applied to the primary side of the high-voltage transformer 3 through the capacitor C.

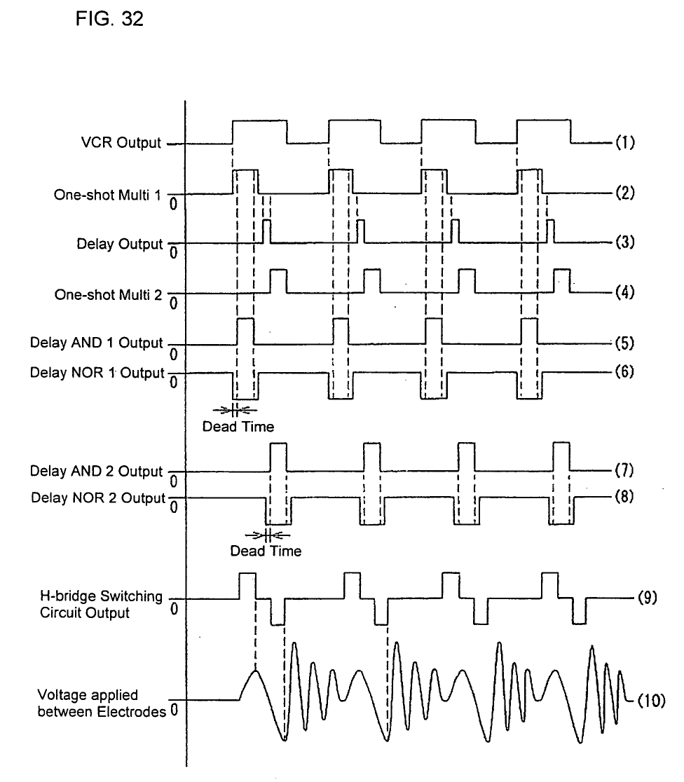

Next, the preliminary circuit for repeatedly outputting a pair of positive and negative pulses from the H-bridge switching circuit 50 by controlling the gate drive circuit 49, and for adjusting the period and the pulse width is explained referring to the timing chart of FIG. 32.

A voltage control oscillator (VCO) 52 repeatedly outputs a rectangular wave, as shown in FIG. 32(1). The repetition frequency can be controlled by a repetition frequency adjuster 51.

A first one-shot multivibrator 53 outputs a pulse that rises when the output (VCO output) of the voltage control oscillator 52 rises, as shown in FIG. 32(2). The pulse width can be adjusted by a first pulse-width adjuster 58.

As shown in FIG. 32(3), a delay circuit 54 outputs a pulse having a certain time width (dead time) that rises when the pulse of the first one-shot multivibrator 53 rises.

As shown in FIG. 32(4), a second one-shot multivibrator 55 outputs a pulse that rises when the output of the delay circuit 54 rises. The pulse width can be adjusted by a second pulse-width adjuster 59.

The pulse provided from the first one-shot multivibrator 53 is input to a first AND gate 46, and the pulse provided from the second one-shot multivibrator 55 is input to a second AND gate 60. An output of a start/stop circuit 44 that can be turned on/off by a start switch 43 is input to these AND gates 46, 60. When it is in the ON state, the pulses of the first and second one-shot multivibrators 53, 55 are respectively input to third and fourth AND gate 47, 56.

An output of the third AND gate 47 is input to a first AND circuit 48 for delay and a first NOR circuit 57 for delay. An output of the fourth AND gate 56 is input to a second AND circuit 61 for delay and a second NOR circuit 62 for delay. Output waveforms of these AND circuits 48, 61 and NOR circuits 57, 62 are shown in FIG. 32(5), (6), (7), (8). In accordance with the outputs, the gate drive circuit 49 outputs gate pulses for the four semiconductor switching devices SW1, SW2, SW3, SW4 of the H-bridge switching circuit 50, and these are switched, as described before.

Therefore, as shown in FIG. 32(9), a pair of positive and negative pulses spaced from each other by a certain time are output as positive and negative pulse waves at a repetition frequency from the H-bridge switching circuit 50. The repetition frequency can be adjusted by the repetition frequency adjuster 51. In addition, the pulse width can be positively or negatively adjusted by the pulse-width adjusters 58, 59.

The positive and negative pulse waves are applied to the primary side of the high voltage transformer 66 through a capacitor C, and become high-voltage periodic waves of damped oscillation waveform, in which a resonant damped oscillation wave is repeated, by the LC component of the high-voltage transformer 66. The high voltage applied between the electrodes 1, 2 is shown in FIG. 32 (10). By adjusting the pulse width by the pulse-width adjusters 58, 59, it is possible to obtain a resonance condition matching the LC component of the high-voltage transformer 66.

As the object to be treated, a silicon substrate with a negative-type resist of 1.2 μm was placed, and then the resist was etched. The resist etching speed was evaluated as the plasma treatment performance.

In addition, when the object is made of a material having poor resistance to heat, a high plasma temperature gives thermal damages to the object. Therefore, the plasma temperature was measured at a position of the outlet 12 by use of a thermocouple.

### Comparative Examples 1, 2

The plasma treatment apparatus for spot treatment shown in FIG. 1 was used. A reaction vessel 10 of this apparatus is substantially the same as the reaction vessel used in Examples 1 to 5 except that the flange portion 6 was not formed. Other configurations are the same as the case of Examples 1 to 5. Plasma 5 was generated under the plasma generating conditions shown in Table 2. As in the case of Examples 1 to 5, the same evaluations were carried out. Results were shown in Table 2.

TABLE 2

| | | | | | | Comparative | Comparative |
|---|---|---|---|---|---|---|---|
| | Example 1 | Example 2 | Example 3 | Example 4 | Example 5 | Example 1 | Example 2 |
| Composition of plasma | Ar + O₂ | Ar + O₂ | Ar + O₂ | Ar + O₂ | Ar + O₂ | Ar + O₂ | Ar + O₂ |
| generation gas | | | | | | | |
| Gas flow amount (liter/min) | Ar 1.75 | Ar 1.75 | Ar 1.75 | Ar 1.75 | Ar 1.75 | Ar 1.75 | Ar 1.75 |
| | O₂ 0.1 | O₂ 0.1 | O₂ 0.1 | O₂ 0.1 | O₂ 0.1 | O₂ 0.022 | O₂ 0.022 |
| Voltage waveform | | | | | | | |
| Rising time (μsec) | 5 | 0.1 | 5 | 1 | 0.1 | 0.018 | 250 |
| Falling time (μsec) | 5 | 5 | 0.1 | 1 | 0.1 | 0.018 | 250 |
| Repetition frequency (kHz) | 50 | 100 | 100 | 100 | 100 | 13.56 MHz | 1 |
| Electric-field intensity (kV/cm) | 5 | 7 | 7 | 7 | 7 | 2 | 10 |
| Input electric power (W) | 200 | 200 | 200 | 200 | 300 | 100 | 400 |
| Etching speed (μm/min) | 2 | 3 | 2 | 4 | 3 | 4 | 0.5 |
| Plasma temperature (° C.) | 60 | 70 | 70 | 80 | 70 | 450 | 50 |

As apparent from Table 2, the plasma temperature is 100° C. or less in the plasma treatment apparatus of Examples 1 to 5, and is much lower than the case of Comparative Example 1, in which a high-frequency voltage of 13.56 MHz was applied. On the other hand, with respect to the etching speed, each of Examples 1 to 5 is substantially equal to Comparative Example 1. Therefore, it is sufficient in plasma treatment capability. In addition, Examples 1 to 5 are faster in the etching speed than Comparative Example 2 with 250 μsec of the rising and falling times. Therefore, it is concluded from a comprehensive standpoint that Examples 1 to 5 are higher in performance than Comparative Examples 1, 2.

### Examples 6 to 10

A plasma treatment apparatus for wide treatment shown in FIG. 22 was used. A reaction vessel 10 of this apparatus is made of quartz glass, and has the inner size of 1 mm×30 mm, which has a slit-like outlet 12 and a hollow flange portion 6 (retention area 15). Other configurations are substantially the same as Examples 1 to 5. Plasma was generated under the plasma generating conditions shown in Table 3. As in the case of Examples 1 to 5, the same evaluations were carried out.

### Comparative Examples 3, 4

A plasma treatment apparatus for wide treatment shown in FIG. 21 was used. A reaction vessel 10 of this apparatus is substantially the same as the reaction vessel used in Examples 6 to 10 except that the flange portion 6 was not formed. Other configurations are substantially the same as Examples 6 to 10. Plasma 5 was generated under the plasma generating conditions shown in Table 3. As in the case of Examples 6 to 10, the same evaluations were carried out. Results of the above evaluations are shown in Table 3.

TABLE 3

| | | | | | Example | Comparative | Comparative |
|---|---|---|---|---|---|---|---|
| | Example 6 | Example 7 | Example 8 | Example 9 | 10 | Example 3 | Example 4 |
| Composition of plasma | Ar + O₂ | Ar + O₂ | Ar + O₂ | Ar + O₂ | Ar + O₂ | Ar + O₂ | Ar + O₂ |
| generation gas | | | | | | | |
| Gas flow amount (liter/min) | Ar 6 | Ar 6 | Ar 6 | Ar 6 | Ar 6 | Ar 6 | Ar 6 |
| | O₂ 0.3 | O₂ 0.3 | O₂ 0.3 | O₂ 0.3 | O₂ 0.3 | O₂ 0.3 | O₂ 0.3 |
| Voltage waveform | | | | | | | |
| Rising time (μsec) | 5 | 0.1 | 5 | 1 | 0.1 | 0.018 | 250 |
| Falling time (μsec) | 5 | 5 | 0.1 | 1 | 0.1 | 0.018 | 250 |
| Repetition frequency (kHz) | 50 | 100 | 100 | 100 | 100 | 13.56 MHz | 1 |
| Electric-field intensity (kV/cm) | 5 | 7 | 7 | 7 | 7 | 2 | 10 |
| Input electric power (W) | 800 | 800 | 800 | 800 | 1200 | 450 | 1300 |
| Etching speed (μm/min) | 8 | 10 | 8 | 15 | 10 | 15 | 1 |
| Plasma temperature (° C.) | 60 | 70 | 70 | 80 | 70 | 450 | 50 |

As apparent from Table 3, the plasma temperature is 100° C. or less in the plasma treatment apparatus of Examples 6 to 10, and is much lower than the case of Comparative Example 3, in which a high-frequency voltage of 13.56 MHz was applied. On the other hand, with respect to the etching speed, each of Examples 6 to 10 is substantially equal to Comparative Example 3. Therefore, it is sufficient in plasma treatment capability. In addition, Examples 6 to 10 is faster in etching speed than Comparative Example 4 with 250 μsec of the rising and falling times. Therefore, it is concluded from a comprehensive standpoint that Examples 6 to 10 are higher in performance than Comparative Examples 3, 4.

### Example 11

A plasma treatment apparatus for spot treatment shown in FIG. 18 was used. A reaction vessel 10 of this apparatus is obtained by forming a tapered nozzle portion 14 with the outlet 12 having the inner diameter of 1 mm at a lower side of the reaction vessel 10 of the Examples 1 to 5. Other configurations are substantially the same as Examples 1 to 5. Plasma 5 was generated under the plasma generating conditions shown in Table 4. As in the case of Examples 1 to 5, the evaluations were carried out.

### Example 12

A plasma treatment apparatus for spot treatment shown in FIG. 15 was used. A reaction vessel 10 of this apparatus is obtained by forming a tapered nozzle portion 14 with the outlet 12 with the inner diameter of 1 mm at a lower side of the reaction vessel 10 of Comparative Examples 1, 2. Other configurations are substantially the same as Examples 1 to 5. Plasma 5 was generated under the plasma generating conditions shown in Table 4. As in the case of Examples 1 to 5, the evaluations were carried out. Results of the above evaluations are shown in Table 4.

TABLE 4

| | Example 11 | Example 12 |
|---|---|---|
| Composition of plasma | Ar + O₂ | Ar + O₂ |
| generation gas | | |
| Gas flow amount (liter/min) | Ar 1.3 | Ar 1.3 |
| | O₂ 0.07 | O₂ 0.07 |
| Voltage waveform | | |
| Rising time (μsec) | 1 | 1 |
| Falling time (μsec) | 1 | 1 |
| Repetition frequency (kHz) | 100 | 100 |
| Electric-field intensity (kV/cm) | 6 | 5 |
| Input electric power (W) | 150 | 150 |
| Etching speed (μm/min) | 4 | 3 |
| Plasma temperature (° C.) | 80 | 80 |

As apparent from Table 4, the flow velocity of the plasma 5 is increased by narrowing the outlet 12 of the reaction vessel 10, so that equivalent performance can be obtained under the conditions of a smaller flow amount and a lower electric power used, as compared with Example 4. However, in the reaction vessel with no flange portion 6, as shown in FIG. 12, when the voltage applied between the electrodes 1, 2 is increased to improve the plasma performance, arc discharge may occur outside the reaction vessel 10 and between the electrodes 1, 2. The conditions of developing the arc discharge vary with a distance between the electrodes 1, 2 or the applied voltage waveform. Therefore, although it is not always so, there is a fear that the arc discharge develops when the electric-field intensity is 10 kV/cm or more.

### Example 13

The same plasma treatment apparatus as Examples 1 to 5 was used. As a plasma generation gas, a mixture gas of 1.75 liter/min of argon and 0.1 liter/min of oxygen was used. As shown in FIG. 10B, a waveform of the voltage applied between the electrodes 1, 2 is obtained by superimposing two pulse-like voltages on a sinusoidal voltage waveform. A repetition frequency of the sinusoidal wave is 50 kHz (the rising and falling times are 5 μsec, and the maximum voltage is 2.5 kV.). The pulse-like high voltages (the rising time is 0.08 μsec.) having a pulse height value of 5 kV were superimposed on this sinusoidal wave. As the timing of superimposing the pulse-like high voltages, the first pulse was superimposed after the elapse of 1 μsec from the occurrence of a change in polarity of the sinusoidal voltage, and the second pulse was superimposed after the elapse of 2 μsec from the first pulse being applied. Except for the above, plasma 5 was generated under the same conditions as Examples 1 to 5, and then etching of resist was performed as in the case of Examples 1 to 5. As a result, the etching speed was 3 μm/min.

### Example 14

The same plasma treatment apparatus as Example 11 was used. As a plasma generation gas, a dry air was used. A voltage having the waveform shown in FIG. 8B was applied between the electrodes 1, 2, while the dry air being supplied at the flow amount of 3 liter/min into the gas flow channel 20. As the waveform conditions, the rising time is 0.1 μsec, the falling time is 0.9 μsec, and the repetition frequency is 500 kHz. Since the plasma generation gas is the dry air, a relatively high electric-field intensity is needed. In this case, it is 20 kV/cm. In addition, the applied electric power is 300 W. Other configurations are substantially the same as Examples 1 to 5.

As an object to be treated, a glass for liquid crystal (a contact angle of water is about 45° before the plasma treatment.) was used. The plasma treatment was performed by spraying the plasma to this object for about 1 second. As a result, the contact angle of water on the glass became 5° or less. Thus, organic materials could be removed from the glass surface in a short time period.

### Example 15

The same plasma treatment apparatus as Example 11 was used. As a plasma generation gas, a mixture gas of 1.5 liter/min of argon and 100 cc/min of hydrogen was used. A voltage having the waveform shown in FIG. 8D was applied between the electrodes 1, 2, while the mixture gas being supplied into the gas flow channel 20. As the waveform conditions, the rising and falling times are 1 μsec, and the repetition frequency is 100 kHz. The electric-field intensity is 7 kV/cm, and the applied electric power is 200 W. Other configurations are substantially the same as Examples 1 to 5.

An object to be treated was formed by screen printing a silver palladium paste on an alumina substrate, and then baking it to obtain a circuit (including bonding pads) thereon. As a result of the XPS analysis of the bonding pads, it was confirmed that a peak of silver oxide exist before the plasma treatment, but this peak changes to the peak of silver metal after the plasma treatment. Thus, the amount of silver oxide was reduced at the bonding pads.

### Example 16

A plasma treatment apparatus shown in FIGS. 23, 24 was used. In this apparatus, electric fields developed between electrode members 1a, 1b and between electrode members 2a, 2b are substantially orthogonal to a flow direction of the plasma generation gas in the discharge space 3. In addition, electric fields developed between the electrode members 1a, 2a, and between the electrode members 1b, 2b are substantially parallel to the flow direction of the plasma generation gas in the discharge space 3.

In the above-described plasma treatment apparatus, a mixture gas of 6 liter/min of argon and 0.3 liter/min of oxygen was used as the plasma generation gas. A voltage having the waveform shown in FIG. 8D was applied between the electrodes 1, 2, while the mixture gas being supplied into the gas flow channel 20. As the waveform conditions, the rising and falling times are 1 μsec, and the repetition frequency is 100 kHz. The electric-field intensity is 7 kV/cm, and the applied electric power is 800 W. Other configurations are substantially the same as Examples 1 to 5. Etching of resist was performed under the above conditions. As a result, the etching speed was 3 μm/min.

### Example 17

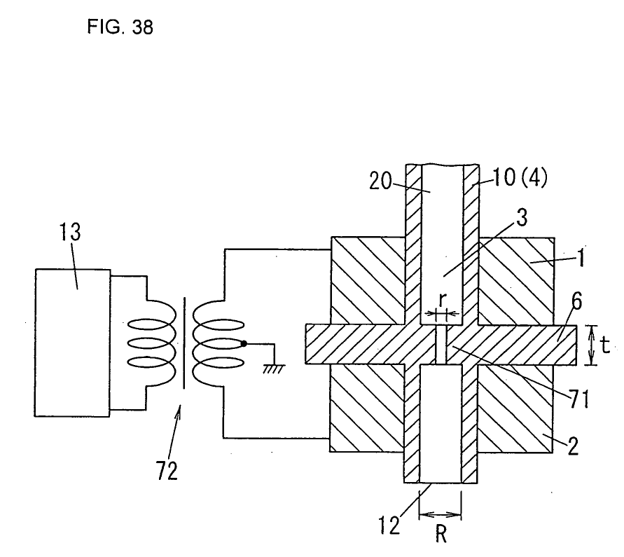

A plasma treatment apparatus shown in FIG. 38 was used. A reaction vessel 10 of this apparatus is of the same configuration as that of FIG. 37, and made of quartz glass. In addition, electrodes 1, 2 for plasma generation are made of SUS 304. The electrodes 1, 2 were formed to allow cooling water to circulate therein. The inner diameter “r” of a projecting portion 71 of the reaction vessel 10 is 1.2 mmφ, and the inner diameter “R” of the other portion is 3 mmφ. The thickness “t” of the flange portion 6 is 5 mm. In addition, a silicon grease was filled as a filling material 70 in a clearance between the electrodes 1, 2 to bring the flange portion 6 into intimate contact with the electrodes 1, 2.

In addition, a power source 13 has a step-up transformer 72, and a mid point of the secondary side of the step-up transformer 72 was grounded. Therefore, the voltage can be applied between the electrodes 1, 2 in a floating state of the electrodes 1, 2 with respect to the ground.

As the plasma generation gas, a mixture gas of 1.58 liter/min of argon and 0.07 liter/min of oxygen was used. The voltage applied between the electrodes 1,2 has a sinusoidal waveform. The rising and falling times are 1.7 μsec, and the repetition frequency is 150 kHz. 3 kV of the voltage was applied to each of the electrodes 1, 2 with respect to the ground. Therefore, the voltage applied between the electrodes 1, 2 is 6 kV, and the electric-field intensity is 12 kV/cm.

As an object to be treated, a negative-type resist was coated on a silicon substrate with the thickness of 1 μm, and then the resist was etched. The etching speed was evaluated as the plasma treatment performance. As a result, the etching speed was 4 μm/min.

### Example 18

A plasma treatment apparatus shown in FIG. 39 was used. Electrodes 1, 2 are made of titanium, and has the length of 1100 mm. An alumina layer having the thickness of 1 mm was formed as a dielectric layer 4 on the electrode surfaces 1, 2 by thermal spraying. In addition, cooling water was circulated in the electrodes 1, 2. These electrodes 1, 2 were arranged in a face-to-face relation so as to be spaced from each other by 1 mm. In a non-discharge state, nitrogen gas was supplied from the upstream side of the discharge space 3 such that a gas flow velocity is 20 m/sec at the outlet 12. To generate the plasma 5, 7 kV of the voltage having a sinusoidal wave of the frequency of 80 kHz was applied to the electrodes 1, 2 from a power source 13 through the step-up transformer 72 of midpoint ground type. Since the step-up transformer 72 of midpoint ground type is used, a float voltage with respect to the ground can be applied to the both electrodes 1, 2. The other configurations are substantially the same as Example 17.

The plasma 5 was generated under the above-described conditions, and then an object to be treated (a glass for liquid crystal) was passed at the speed of 8 m/min, while being spaced from the downstream side of the outlet 12 by the distance of 5 mm. A contact angle of water was about 50° before the treatment, but it became about 5° after the treatment. In addition, a color filter for liquid crystal made of an acrylic resin was treated. The contact angle of water was about 50° before the treatment, but it was improved to about 15° after the treatment.

### Example 19

The same apparatus as Example 18 was used. About 0.05% by volume ratio of oxygen was mixed with nitrogen, and a resultant mixture was supplied as the plasma generation gas such that its gas flow velocity is 10 m/sec at the outlet 12. To generate the plasma 5, 6 kV of the voltage having a sinusoidal wave of the frequency of 80 kHz was applied to the electrodes 1, 2 through a step-up transformer 72 of midpoint ground type. Since the step-up transformer 72 of midpoint ground type is used, a float voltage with respect to the ground can be applied to the both electrodes 1, 2. The other configurations are substantially the same as Example 18.

The plasma 5 was generated under the above-described conditions, and then an object to be treated (a glass for liquid crystal) was passed at the speed of 8 m/min, while being spaced from the downstream side of the outlet 12 by the distance of 5 mm. A contact angle of water was about 50° before the treatment, but it became about 5° after the treatment. In addition, a color filter for liquid crystal made of an acrylic resin was treated. The contact angle of water was about 50° before the treatment, but it was improved to about 10° after the treatment.

### Example 20

The same apparatus as Example 18 was used. About 0.1% by volume ratio of air was mixed with nitrogen, and a resultant mixture was supplied as the plasma generation gas such that its gas flow velocity is 10 m/sec at the outlet 12. To generate the plasma 5, 6 kV of the voltage having a sinusoidal wave of the frequency of 80 kHz was applied to the electrodes 1, 2 through a step-up transformer 72 of midpoint ground type. Since the step-up transformer 72 of midpoint ground type is used, a float voltage with respect to the ground can be applied to the both electrodes 1, 2. The other configurations are substantially the same as Example 18.

The plasma 5 was generated under the above-described conditions, and then an object to be treated (a glass for liquid crystal) was passed at the speed of 8 m/min, while being spaced from the downstream side of the outlet 12 by the distance of 5 mm. A contact angle of water was about 50° before the treatment, but it became about 5° after the treatment. In addition, a color filter for liquid crystal made of an acrylic resin was treated. The contact angle of water was about 50° before the treatment, but it was improved to about 8° after the treatment.

### Example 21

The same apparatus as Example 18 was used. About 30% by volume ratio of CF₄ was mixed with oxygen, and a resultant mixture was supplied as the plasma generation gas such that its gas flow velocity is 10 m/sec at the outlet 12. To generate the plasma 5, 6 kV of the voltage having a sinusoidal wave of the frequency of 80 kHz was applied to the electrodes 1, 2 through a step-up transformer 72 of midpoint ground type. Since the step-up transformer 72 of midpoint ground type is used, a float voltage with respect to the ground can be applied to the both electrodes 1, 2. The other configurations are substantially the same as Example 18.

The plasma 5 was generated under the above-described conditions, and then an object to be treated (a sample obtained by coating a resist on a glass for liquid crystal with the thickness of 1 μm) was passed at the speed of 1 m/min, while being spaced from the downstream side of the outlet 12 by the distance of 5 mm. As a result, the resist thickness became 5000 Å. In this case, the plasma treatment was performed while the substrate being heated at 150° C.

In each of Examples 1 to 21, a sufficient plasma treatment capability was obtained at a reduced plasma temperature with the discharge being stably maintained.

Industrial Applicability

Thus, since the plasma treatment apparatus of the present invention has the capability of improving a plasma-treatment efficiency and reducing the plasma temperature despite the plasma generated under a pressure substantially equal to atmospheric pressure, it can be utilized for not only objects, to which a conventional plasma treatment is available, but also another objects, to which the conventional plasma treatment is not available because the treatment temperature is high. In particular, it is effective to perform cleaning of the object's surface.

1. A plasma treatment apparatus for developing a discharge in a discharge space under a pressure substantially equal to atmospheric pressure by arranging a plurality of electrodes to define said discharge space therebetween, disposing a dielectric material at a discharge-space side of at least one of said electrodes, and applying a voltage between said electrodes, while supplying a plasma generation gas into said discharge space, and for providing a plasma generated by said discharge from said discharge space,
wherein a waveform of said voltage applied between said electrodes is an alternating voltage waveform without rest period, at least one of rising and falling times of said alternating voltage waveform is 100 μsec or less, a repetition frequency is in a range of 0.5 to 1000 kHz, and an electric-field intensity applied between said electrodes is in a range of 0.5 to 200 kV/cm.

2. The plasma treatment apparatus as set forth in claim 1, wherein a pulse-like high voltage is superimposed on said voltage having the alternating voltage waveform without rest period applied between said electrodes.

3. The plasma treatment apparatus as set forth in claim 2, wherein said pulse-like high voltage is superimposed after the elapse of a required time period from the occurrence of a change in voltage polarity of the alternating voltage waveform.

4. The plasma treatment apparatus as set forth in claim 2, wherein said pulse-like high voltage is superimposed at plural times within one period of the alternating voltage waveform.

5. The plasma treatment apparatus as set forth in claim 2, wherein a rising time of said pulse-like high voltage is 0.1 μsec or less.

6. The plasma treatment apparatus as set forth in claim 2, wherein a pulse height value of said pulse-like high voltage is equal to or more than a maximum voltage value of the alternating voltage waveform.

7. The plasma treatment apparatus as set forth in claim 1, wherein the alternating voltage waveform without rest period applied between said electrodes is formed by superimposing alternating voltage waveforms having a plurality kinds of frequencies.

8. A plasma treatment apparatus for developing a discharge in a discharge space under a pressure substantially equal to atmospheric pressure by arranging a plurality of electrodes to define said discharge space therebetween, disposing a dielectric material at a discharge-space side of at least one of said electrodes, and applying a voltage between said electrodes, while supplying a plasma generation gas into said discharge space, and for providing a plasma generated by said discharge from said discharge space,
wherein a waveform of said voltage applied between said electrodes is a pulse-like waveform.

9. The plasma treatment apparatus as set forth in claim 8, wherein a rising time of said pulse-like waveform is 100 μsec or less.

10. The plasma treatment apparatus as set forth in claim 8, wherein a falling time of said pulse-like waveform is 100 μsec or less.

11. The plasma treatment apparatus as set forth in claim 8, wherein a repetition frequency of said pulse-like waveform is in a range of 0.5 to 1000 kHz.

12. The plasma treatment apparatus as set forth in claim 8, wherein an electric-field intensity applied between said electrodes is in a range of 0.5 to 200 kV/cm.

13. The plasma treatment apparatus as set forth in claim 1 or 8, wherein said electrodes are disposed such that an electric field developed in said discharge space by applying said voltage between said electrodes is substantially parallel to a flow direction of said plasma generation gas in said discharge space.

14. The plasma treatment apparatus as set forth in claim 1 or 8, wherein said electrodes are disposed such that an electric field developed in said discharge space by applying said voltage between said electrodes is substantially orthogonal to a flow direction of said plasma generation gas in said discharge space.

15. The plasma treatment apparatus as set forth in claim 1 or 8, wherein a flange portion, in which a part of said plasma generation gas supplied into said discharge space is allowed to stay, is formed between said electrodes.

16. A plasma treatment apparatus comprising a reaction vessel with an opened end as an outlet and at least one pair of electrodes, said apparatus for generating a plasma in said reaction vessel under a pressure substantially equal to atmospheric pressure by applying a voltage between said electrodes, while supplying a plasma generation gas into said reaction vessel, and for providing said plasma from the outlet of said reaction vessel,
wherein said electrodes are disposed with a flange portion being formed between said electrodes and outside said reaction vessel, so that an electric field developed in a discharge space by applying said voltage between said electrodes is substantially parallel to a flow direction of said plasma generation gas in said discharge space.

17. The plasma treatment apparatus as set forth in claim 16, wherein a waveform of said voltage applied between said electrodes is a pulse-like waveform or an alternating voltage waveform without rest period.

18. The plasma treatment apparatus as set forth in claim 17, wherein a rising time of the pulse-like waveform or the alternating voltage waveform without rest period is 100 μsec or less.

19. The plasma treatment apparatus as set forth in claim 17, wherein a falling time of the pulse-like waveform or the alternating voltage waveform without rest period is 100 μsec or less.

20. The plasma treatment apparatus as set forth in claim 17, wherein a repetition frequency of the pulse-like waveform or the alternating voltage waveform without rest period is in a range of 0.5 to 1000 kHz.

21. The plasma treatment apparatus as set forth in claim 16, wherein an electric-field intensity applied between said electrodes is in a range of 0.5 to 200 kV/cm.

22. The plasma treatment apparatus as set forth in claim 16, wherein said discharge space is partially narrowed.

23. The plasma treatment apparatus as set forth in claim 16, wherein a filling material is provided between said electrode and said flange portion, so that said electrode is connected to said flange portion through said filling material.

24. The plasma treatment apparatus as set forth in any one of claims 1, 8 and 16, wherein said voltage is applied such that both of said electrodes are in a floating state with respect to the ground potential.

25. The plasma treatment apparatus as set forth in any one of claims 1, 8 and 16, wherein said plasma generation gas includes a rare gas, nitrogen, oxygen, air, hydrogen or a mixture thereof.

26. The plasma treatment apparatus as set forth in any one of claims 1, 8 and 16, wherein said plasma generation gas is a mixture gas obtained by mining CF₄, SF₆, NF₃ or a mixture thereof with a rare gas, nitrogen, oxygen, air, hydrogen or a mixture thereof at a volume ratio of 2 to 40%.

27. The plasma treatment apparatus as set forth in claim 25, wherein said plasma generation gas is a mixture gas obtained by mixing oxygen such that a volume ratio of oxygen with respect to nitrogen is 1% or less.

28. The plasma treatment apparatus as set forth in claim 25, wherein said plasma generation gas is a mixture gas obtained by mixing the air such that a volume ratio of the air with respect to nitrogen is 4% or less.

29. The plasma treatment apparatus as set forth in any one of claims 1, 8 and 16, wherein said plasma generation gas is supplied into said discharge space such that a flow velocity of said plasma generation gas provided from the outlet in a non-discharge state is in a range of 2 m/sec to 100 m/sec.

30. A plasma treatment method comprising the step of performing a plasma treatment with use of the plasma treatment apparatus as set forth in any one of claims 1, 8 and 16.
